(19) United States
(12) Patent Application Publication
(10) Pub. No.: US 2026/0074086 A1
(43) Pub. Date: Mar. 12, 2026

(54) Integrated Battery and Method of Manufacturing the Same

(71) Applicant: LG Energy Solution, Ltd., Seoul (KR)

(72) Inventors: Dong Myung Kim, Daejeon (KR); Je Young Kim, Daejeon (KR); Dong Myung Shin, Daejeon (KR)

(73) Assignee: LG Energy Solution, Ltd., Seoul (KR)

(21) Appl. No.: 19/320,086

(22) Filed: Sep. 5, 2025

(30) Foreign Application Priority Data
Sep. 6, 2024 (KR) 10-2024-0121832
Sep. 4, 2025 (KR) 10-2025-0125548

(51) Int. Cl. G21H 1/04; H01L 23/58

(52) U.S. Cl. CPC G21H 1/04; H10W 42/00

(57) ABSTRACT

An integrated battery may include a substrate including a first material, a plurality of second material layers each including a second material, and a plurality of radiation sources configured to apply radiation to the substrate and the plurality of second material layers. The first material may have a polarity opposite a polarity of the second material. The plurality of second material layers may contact the substrate, and each of the plurality of radiation sources may have a tapered shape.

### CROSS-REFERENCE TO RELATED APPLICATIONS

This application claims priority under 35 U.S.C. § 119 to Korean Patent Application No. 10-2024-0121832, filed on Sep. 6, 2024, and Korean Patent Application No. 10-2025-0125548, filed on Sep. 4, 2025, the entire contents of which are incorporated by reference herein.

### TECHNICAL FIELD

The present disclosure relates to an integrated battery and a method of manufacturing an integrated battery.

### BACKGROUND

An isotope battery is a type of battery that produces electricity using radiation emitted during the decay of a radioactive isotope. Generally, isotope batteries produce power using a radioactive isotope emitting beta rays and/or alpha rays and semiconductor materials. Isotope batteries operate by directly converting energy emitted during radioactive decay into electric energy.

Isotope batteries are capable of continuously producing energy during the half-life of the radioactive isotope and thus the lifespan thereof is very long. In addition, isotope batteries are capable of constantly supplying power regardless of an environment and thus can be used stably even in extreme environments.

### SUMMARY

### Technical Problem

There is a need for integrated, isotope batteries that have improved efficiency and for improved methods of making integrated batteries. The present disclosure is directed to providing an integrated battery and a manufacturing method thereof. It should be understood that the integrated batteries referred to in the present disclosure are isotope batteries.

### Technical Solution

Aspects of the present disclosure are directed to an integrated battery. The integrated battery includes a substrate comprising a first material, a plurality of second material layers each comprising a second material, and a plurality of radiation sources configured to apply radiation to the substrate and the plurality of second material layers. The first material has a polarity opposite a polarity of the second material. The plurality of second material layers contact the substrate. Each of the plurality of radiation sources has a tapered shape.

The substrate may include a plurality of holes extending into the substrate in a first direction from a first surface of the substrate, wherein the first direction is perpendicular to the first surface of the substrate, and each radiation source of the plurality of radiation sources may be in a respective one of the plurality of holes.

Each hole of the plurality of holes may have a tapered shape.

Each radiation source of the plurality of radiation sources has a cross-sectional area in a plane normal to the first direction and the cross-sectional area may decrease as a distance from the first surface of the substrate in the first direction increases.

Each second material layer of the plurality of second material layers may have a uniform thickness.

Each second material layer of the plurality of second material layers may be between the substrate and a respective radiation source of the plurality of radiation sources.

The plurality of holes may be arranged in a honeycomb structure in a plane normal to the first direction.

The plurality of holes may form a plurality of hole arrays such that the plurality of holes are aligned in a second direction and such that the plurality of holes are staggered in a third direction, wherein the second direction is normal to the first direction, and wherein the third direction is normal to the first direction and the second direction.

The plurality of holes may be arranged in a matrix.

Each hole of the plurality of holes may have an elongated shape extending in a third direction, wherein the third direction is perpendicular to the first direction.

Each hole of the plurality of holes may have a roughened surface.

Each hole of the plurality of holes may have a star shaped cross-sectional area in a plane perpendicular to the first direction.

An interface between the substrate and each second material layer of the plurality of second material layers may be roughened.

An interface between each second material layer of the plurality of second material layers and each radiation source of the plurality of radiation sources may be roughened.

Each radiation source of the plurality of radiation sources may comprise a radioactive isotope that emits beta rays.

Each radiation source of the plurality of radiation sources may comprise a radioactive isotope that emits alpha rays.

The integrated battery may further include a plurality of lower scintillation patterns, wherein the plurality of lower scintillation patterns comprises a material that emits photons in response to the alpha rays.

Each lower scintillation pattern of the plurality of lower scintillation patterns may be between a respective radiation source of the plurality of radiation sources and a respective second material layer of the plurality of second material layers.

The integrated battery may further include a plurality of upper scintillation patterns, wherein the plurality of upper scintillation layers comprises a material that emits photons in response to the alpha rays.

Each upper scintillation pattern of the plurality of upper scintillation patterns may be on an upper surface of a respective radiation source of the plurality of radiation sources.

Each radiation source of the plurality of radiation sources may be surrounded by a respective upper scintillation pattern of the plurality of upper scintillation patterns and a respective lower scintillation pattern of the plurality of lower scintillation patterns.

Each upper scintillation pattern of the plurality of upper scintillation patterns may form a continuous layer with a respective lower scintillation pattern of the plurality of lower scintillation patterns.

Aspects of the present disclosure are directed to an integrated battery. The integrated battery includes a first battery layer, a second battery layer, and an insulating layer between the first battery layer and the second battery layer. The first battery layer comprises a first substrate comprising a first material, a plurality of second material layers each comprising a second material, and a plurality of first radiation sources. The first substrate comprises a plurality of first holes. Each first radiation source of the plurality of first radiation sources is in a respective one of the plurality of first holes. Each of the plurality of second material layers is between the substrate and a respective one of the plurality of first radiation sources. The first material has a polarity opposite a polarity of the second material. The second battery layer comprises a second substrate comprising a third material, a plurality of fourth material layers each comprising a fourth material, and a plurality of second radiation sources. The second substrate comprises a plurality of second holes. Each second radiation source of the plurality of second radiation sources is in a respective one of the plurality of second holes. Each of the plurality of fourth material layers is between the second substrate and a respective one of the plurality of second radiation sources. The third material has a polarity opposite a polarity of the fourth material.

The integrated battery may further include a plurality of vias extending through the insulating layer, the plurality of vias connecting the first battery layer and the second battery layer.

Each of the plurality of vias may be in contact with one of the plurality of second material layers of the first battery layer and the second substrate of the second battery layer.

The plurality of vias may electrically connect the first battery layer and the second battery layer in series.

The second material of the plurality of second material layers of the first battery layer may have the same polarity as the third material of the second substrate of the second battery layer.

The plurality of vias may electrically connect the first battery layer and the second battery layer in parallel.

The second material of the plurality of second material layers of the first battery layer may have polarity opposite to polarity of the third material of the second substrate of the second battery layer.

Each of the plurality of first radiation sources and each of the plurality of second radiation sources may have a tapered shape.

Each of the plurality of second material layers may have a cup shape, and each of the plurality of fourth material layers may have a cup shape.

Each of the plurality of second material layers may have a uniform thickness, and each of the plurality of fourth material layers may have a uniform thickness.

Each of the plurality of first holes may have a tapered shape and each of the plurality of second holes may have a tapered shape.

The integrated battery may further include a core layer including peripheral transistors, and the first battery layer may be on the core layer.

The peripheral transistors may form a voltage regulator configured to adjust output voltages of the first battery layer and second battery layer.

Aspects of the present disclosure are directed to an integrated battery. The integrated battery includes a substrate comprising a first material, wherein the substrate comprises a plurality of holes; a plurality of radiation sources in the plurality of holes, and a plurality of second material layers each comprising a second material. Each radiation source of the plurality of radiation sources has a necked shape. Each of the plurality of second material layers is between a respective radiation source of the plurality of radiation sources and the substrate. The first material has a polarity opposite a polarity of the second material.

Each hole of the plurality of holes may have a necked shape.

### Advantageous Effects

An integrated battery according to aspects of the present disclosure includes an oblique interface between a substrate and a radiation source. Accordingly, energy efficiency of the radiation source may improve.

Effects achieved from aspects of the present disclosure are not limited to the above-described effects, and other effects that are not described herein will be clearly derived and understood by those of ordinary skill in the art to which the aspects of the present disclosure pertain from the following description. That is, unintended effects achieved when the aspects of the present disclosure are implemented may be derived by those of ordinary skill in the art from the aspects of the present disclosure.

### BRIEF DESCRIPTION OF DRAWINGS

Aspects of the present disclosure will be more clearly understood from the following detailed description in conjunction with the accompanying drawings in which:

FIG. 1 is a flowchart of a method of manufacturing an integrated battery.

FIG. 2 is a top plan view illustrating a step of a method of manufacturing an integrated battery according to aspects.

FIG. 3 is a cross-sectional view taken along line 2I-2I′ of FIG. 2.

FIG. 4 is a top plan view illustrating a step of a method of manufacturing an integrated battery according to aspects.

FIG. 5 is a cross-sectional view taken along line 4I-4I′ of FIG. 4.

FIG. 6 is a top plan view illustrating a step of a method of manufacturing an integrated battery according to aspects.

FIG. 7 is a cross-sectional view taken along line 6I-6I′ of FIG. 6.

FIG. 8 is a top plan view illustrating a step of a method of manufacturing an integrated battery according to aspects.

FIG. 9 is a cross-sectional view taken along line 8I-8I′ of FIG. 8.

FIG. 10 is a top plan view illustrating a step of a method of manufacturing an integrated battery according to aspects.

FIG. 11 is a cross-sectional view taken along line 10I-10I′ of FIG. 10.

FIG. 12 is a cross-sectional view of an integrated battery according to aspects.

FIG. 13 is a flowchart of a method of manufacturing an integrated battery.

FIGS. 14 to 16 illustrate sequential steps of a method of manufacturing an integrated battery according to aspects.

FIG. 17 is a flowchart of a method of manufacturing an integrated battery.

FIGS. 18 to 21 are cross-sectional views illustrating sequential steps of a method of manufacturing an integrated battery according to aspects.

FIG. 22 is a plan view illustrating a step of a method of manufacturing an integrated battery according to aspects.

FIG. 23 is a cross-sectional view taken along line 22I-22I′ of FIG. 22.

FIG. 24 is a cross-sectional view illustrating a step of a method of manufacturing an integrated battery according to aspects.

FIG. 25 is a diagram illustrating an integrated battery according to an aspect.

FIG. 26 is a plan view of an integrated battery according to aspects.

FIG. 27 is a cross-sectional view taken along line 26I-26I′ of FIG. 26.

FIG. 28 is a plan view of an integrated battery according to aspects.

FIG. 29 is a cross-sectional view taken along line 28I-28I′ of FIG. 28.

FIG. 30 is a plan view of an integrated battery according to aspects.

FIG. 31 is a cross-sectional view taken along line 30I-30I′ of FIG. 30.

FIG. 32 is a plan view of an integrated battery according to aspects.

FIG. 33 is a cross-sectional view taken along line 32I-32I′ of FIG. 32.

FIG. 34 is a plan view illustrating a step of a method of manufacturing an integrated battery according to an aspect.

FIG. 35 is a cross-sectional view taken along line 34I-34I′ of FIG. 34.

FIG. 36 is a plan view illustrating a step of a method of manufacturing an integrated battery according to an aspect.

FIG. 37 is a cross-sectional view taken along line 36I-36I′ of FIG. 36.

FIG. 38 is a cross-sectional view of an integrated battery according to an aspect.

FIG. 39 is a flowchart of a method of manufacturing an integrated battery according to an aspect.

FIGS. 40 to 46 are cross-sectional views illustrating sequential steps of a method of manufacturing an integrated battery according to an aspect.

Like reference numerals and designations refer to the same elements in the figures. Additionally, various elements and areas of the figures are schematically depicted and are not necessarily drawn to scale. Accordingly, the aspects of the present disclosure are not limited to the relative sizes or spacing depicted in the accompanying drawings.

### DETAILED DESCRIPTION

Hereinafter, aspects of the present disclosure will be described in detail with reference to the accompanying drawings. Before describing aspects of the present disclosure, it should be understood that the terms or expressions used in the present specification and claims should not be construed as being limited to generally understood or common dictionary definitions, and should be understood according to meanings and concepts corresponding to the technology of the present disclosure on the basis of the principle that the inventor(s) can appropriately define the terms or expressions to optimally explain the technical features of present disclosure.

Aspects set forth herein and configurations illustrated in the drawings are only some aspects of the present disclosure and do not reflect all the technical ideas of the present disclosure. Thus it should be understood that various equivalents and modifications may have been made at the filing date of the present application.

Well-known configurations or functions related to aspects of the present disclosure are not described in detail when it is determined that they would obscure the subject matter of the present disclosure due to unnecessary detail.

Because aspects of the present disclosure are provided to more fully explain the technical features of the present disclosure to those of ordinary skill in the art, the shapes, sizes, etc. of components illustrated in the drawings may be exaggerated, omitted, or schematically illustrated for clarity. Therefore, it should be understood that the sizes or proportions of components illustrated in the drawings may not fully reflect the actual sizes or proportions thereof.

### First and Second Aspects

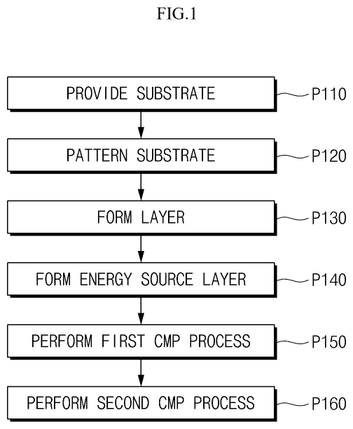

FIG. 1 is a flowchart of a method of manufacturing an integrated battery.

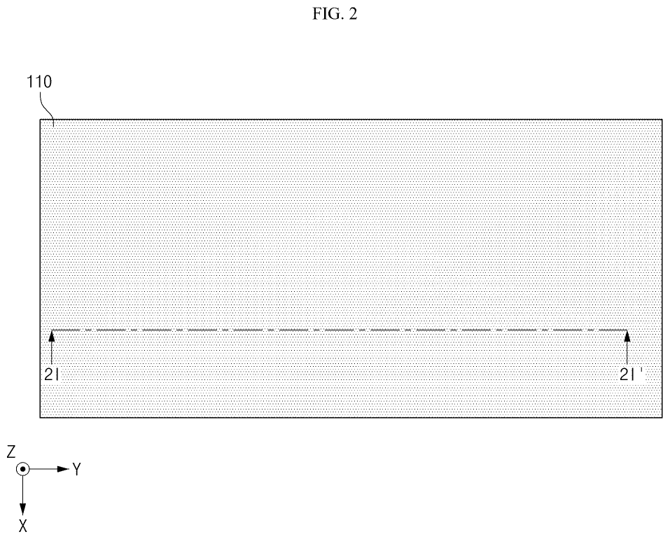

FIG. 2 is a top plan view illustrating a step of a method of manufacturing an integrated battery according to aspects.

FIG. 3 is a cross-sectional view taken along line 2I-2I′ of FIG. 2.

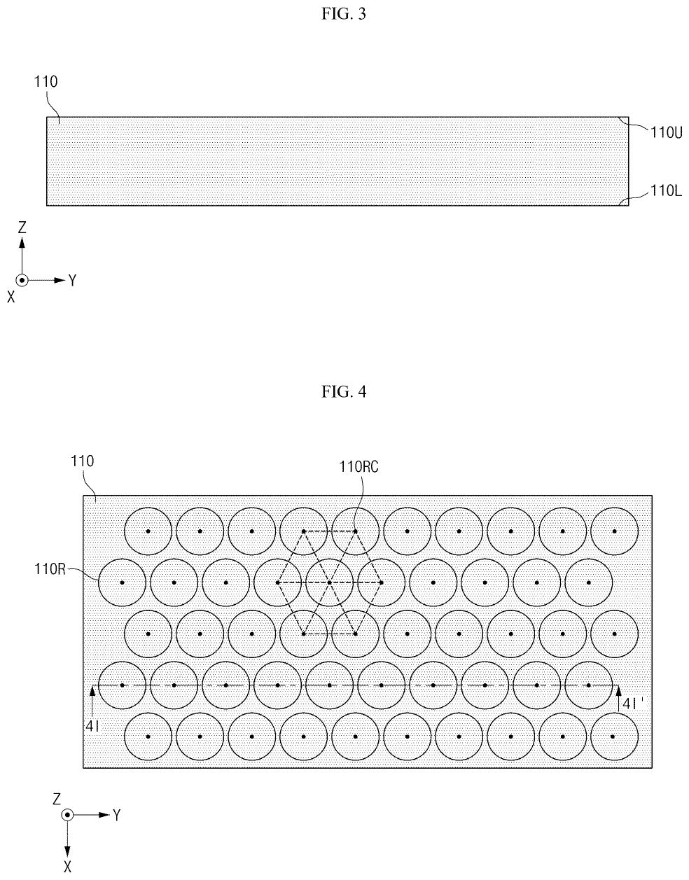

FIG. 4 is a top plan view illustrating a step of a method of manufacturing an integrated battery according to aspects.

FIG. 5 is a cross-sectional view taken along line 4I-4I′ of FIG. 4.

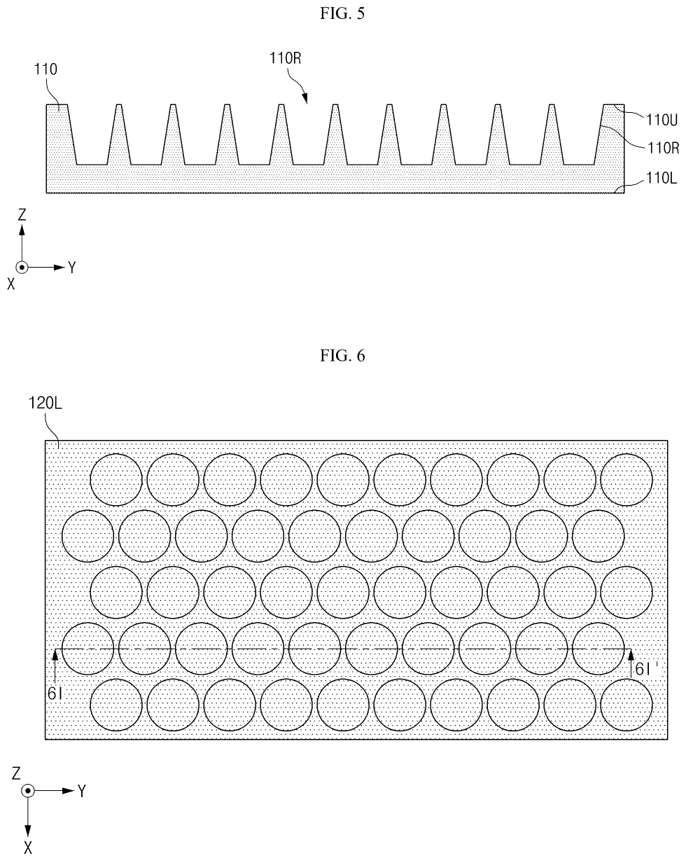

FIG. 6 is a top plan view illustrating a step of a method of manufacturing an integrated battery according to aspects.

FIG. 7 is a cross-sectional view taken along line 6I-6I′ of FIG. 6.

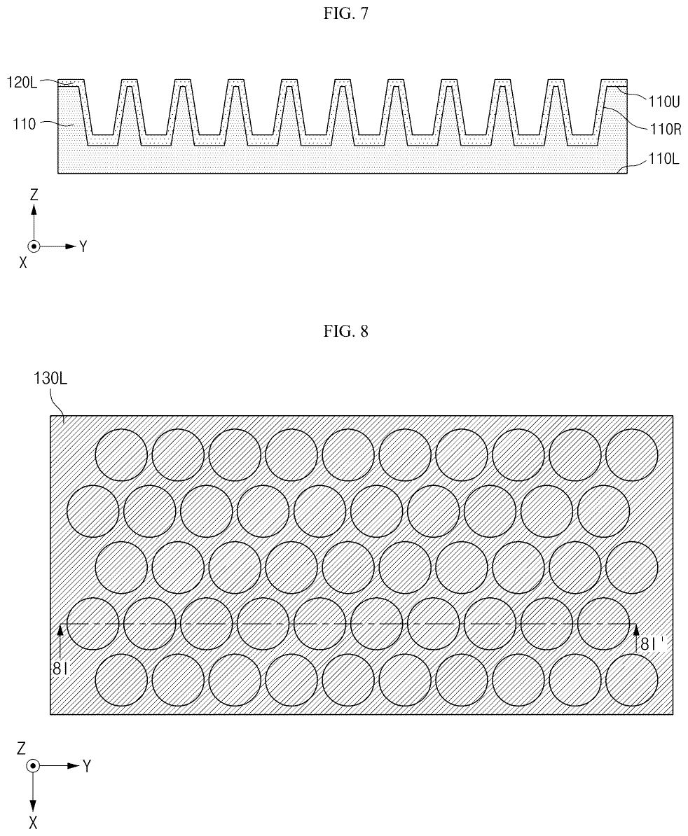

FIG. 8 is a top plan view illustrating a step of a method of manufacturing an integrated battery according to aspects.

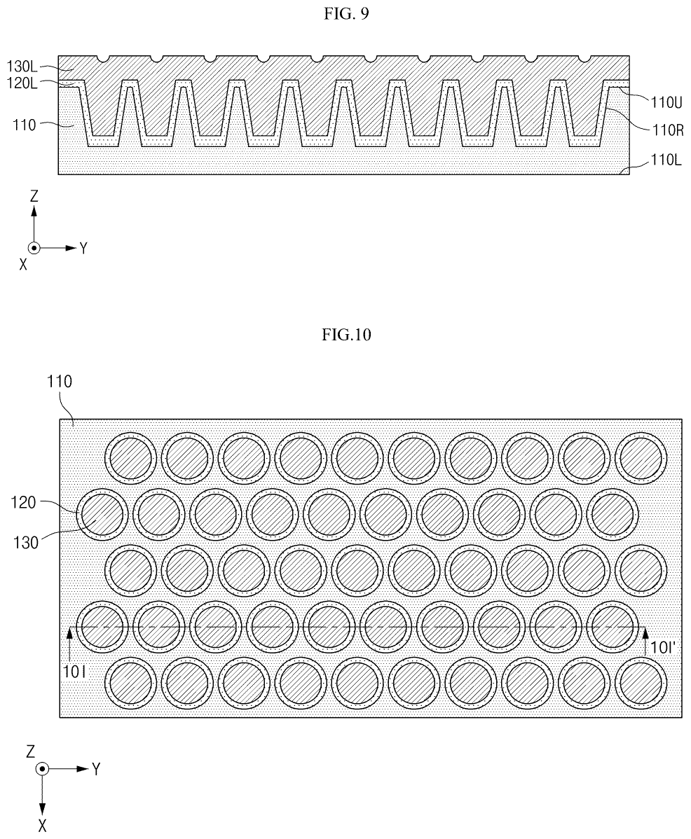

FIG. 9 is a cross-sectional view taken along line 8I-8I′ of FIG. 8.

FIG. 10 is a top plan view illustrating a step of a method of manufacturing an integrated battery according to aspects.

FIG. 11 is a cross-sectional view taken along line 10I-10I′ of FIG. 10.

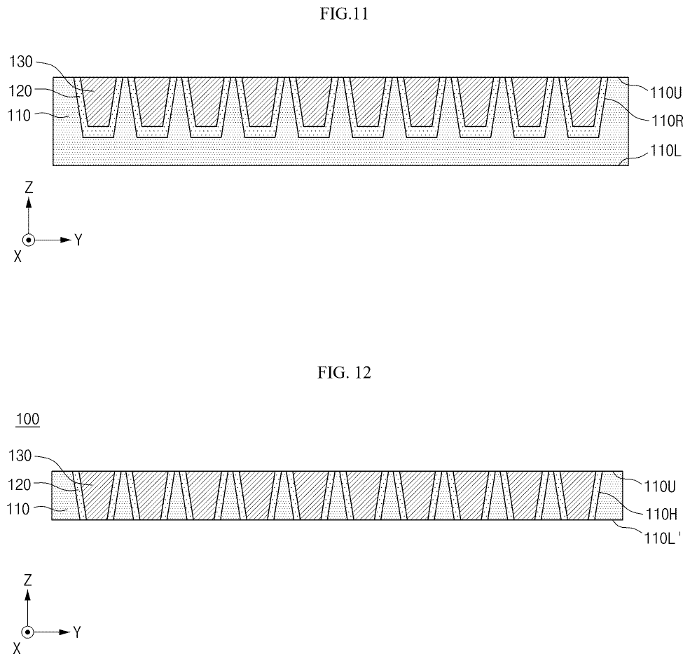

FIG. 12 is a cross-sectional view of an integrated battery according to aspects.

Referring to FIGS. 1 to 3, in step P110 of the method of manufacturing an integrated battery of FIG. 1, a substrate 110 may be provided. The substrate 110 may comprise a first surface and a second surface opposite the first surface in the substrate thickness direction, the Z-axis direction. The first surface and the second surface may be an upper surface 110U and a lower surface 110tL of the substrate 110, respectively. A thickness of the substrate 110 refers to an average distance from the first surface of the substrate 110 to the second surface of the substrate in the substrate thickness direction.

Two directions substantially parallel to an upper surface 110U of the substrate 110 will be defined as an X-axis direction and a Y-axis direction, and a direction substantially perpendicular to the X-axis direction and the Y-axis direction will be defined as a Z-axis direction. The X-axis direction, the Y-axis direction, and the Z-axis direction may be substantially perpendicular to one another.

The substrate 110 may comprise a first material. According to aspects of the present disclosure, the first material of the substrate 110 may include diamond, SiC, GaN, Bi₂O₃/GeO₂, Sm₂O₃/Bi₂O₃/GeO₂, Sm₂O₃/Bi₂O₃/B₂O₃, Sm₂O₃/Bi₂O₃/GeO₂/B₂O₃, or sapphire.

The first material of the substrate 110 may be processed by ion implantation or ion diffusion. The first material of the substrate 110 may be doped with a first conductivity type dopant. The first conductivity type dopant may be a p-type dopant or an n-type dopant.

The p-type dopant may include at least one of boron (B), aluminum (Al), gallium (Ga), or indium (In). In some aspects, the p-type dopants may include beryllium (Be), magnesium (Mg), or zinc (Zn). The n-type dopant may include at least one of nitrogen (N), phosphorus (P), arsenic (As), or antimony (Sb). In some aspects, the n-type dopants may include silicon (Si), germanium (Ge), or tellurium (Te).

The first material of the substrate 110 may include a metal oxide with band gap energy of 2.7 eV or more. In some aspects, the first material of the substrate 110 may include a material represented by AMO₃, where, A is at least one element selected from La, Ba, Sr, or K, and M is at least one element selected from Al, In, Ga, Ti, Sn, Hf, Ta, or Zr.

For example, the first material of the substrate 110 may include at least one of BaSnO₃, BaHfO₃, BaZrO₃, BaHf₁₋ₓTiₓO₃ (where, 0<x<1), Ba₁₋ₓLaₓSnO₃ (where, 0<x<1), Bi₄Ge₃O₁₂, Al₂O₃, Y₂O₃, La₂O₃, Ga₂O₃, Bi₂O₃, ZrO₂, HfO₂, Ta₂O₅, TiO₂, LaInO₃, LaGaO₃, SrZrO₃, SrHfO₃, SrTaO₇, LaIn₁₋ₓGaxO₃ (where, 0<x<1), LaGaO₃, SrTiO₃, KTaO₃, HfSiO₄, Ta₃Ti₂Ox (where, 0<x<1), or LaAlO₃.

Referring to FIGS. 1, 4, and 5, in step P120 of the method of manufacturing an integrated battery illustrated in FIG. 1, the substrate 110 may be patterned. As described herein, patterning the substrate 110 may include removing material from a surface of the substrate 110 to form a plurality of recesses 110R in the substrate 110. The plurality of recesses 110R may be formed in the upper surface 110U or the lower surface 110L of the substrate. In the aspect depicted in FIGS. 4 and 5, the plurality of recesses 110R are formed in the upper surface 110U of the substrate 110. The plurality of recesses 110R may be in any suitable arrangement or pattern.

The substrate 110 may be patterned by reactive ion etching (RIE) including low-temperature etching or ion beam etching. The substrate 110 may be patterned by laser beams. The substrate 110 may be patterned by anisotropic wet etching.

Before the substrate 110 is patterned, a mask may be deposited on at least a portion of the first surface or the second surface of the substrate 110. The mask may be formed by photolithography. The mask may expose a portion of the substrate 110. The portion of the substrate 100 exposed by the mask may be etched to form a plurality of recesses 110R. The mask may cover a non-etched portion of the substrate 110, i.e., a portion of the substrate 100 between the plurality of recesses 110R. A hard mask may be additionally provided between the mask and the substrate 110.

The plurality of recesses 110R may be formed by etching the substrate 110. According to one or more aspects, the plurality of recesses 110R may have a circular shape when viewed from above. When the plurality of recesses 110R have the circular shape when viewed from above, the plurality of recesses 110R may have a circular cross-sectional shape in a plane normal to the Z-axis direction.

According to one or more aspects, the plurality of recesses 110R may be arranged in a honeycomb structure. It may be understood that when the plurality of recesses 110R are arranged in the honeycomb structure, the centers of the plurality of recesses 110R are at the vertices and centers of a plurality of regular hexagons that have the same size and fill a plane.

Each of the plurality of recesses 110R may have a variable width in the X-axis direction, the Y-axis direction, or both the X and Y-axis directions at different positions along the Z-axis direction. For example, a cross-sectional area of each of the plurality of recesses 110R in a plane extending the X-axis direction and the Y-axis direction may vary along the Z-axis direction. In a specific example, each of the plurality of recesses 110R may have a tapered shape in the Z-axis direction. Each of the plurality of recesses 110R may extend from the upper surface 110U of the substrate 110 in the Z-axis direction into a body of the substrate 110. In one or more aspects, the cross-sectional area of each of the plurality of recesses 110R may decrease as a distance from the upper surface 110U of the substrate 110 increases. A first cross-sectional area of each of the plurality of recesses 110R at a first depth from the upper surface 110U of the substrate 110 may be less than a second cross-sectional area of each of the plurality of recesses 110R at a second depth from the upper surface of the substrate 110 when the second depth is less than the first depth.

Referring now to FIGS. 1, 6, and 7, in step P130 of the method of manufacturing an integrated battery of FIG. 1, a second material layer 120L may be formed. The second material layer 120L may have a uniform thickness. In one or more aspects, the second material layer 120L may have a conformal shape to the substrate 110. It may be understood that when the second material layer 120L has the conformal shape, a shape of a structure onto which the second material layer 120L is formed (i.e., the substrate 110 and the plurality of recesses 110R) is transferred to the shape of the second material layer 120L.

The second material layer 120L may be formed by depositing it onto the substrate 110 via a process such as chemical vapor deposition (CVD) or physical vapor deposition (PVD), but is not limited thereto. The layer 120L may be formed by oxidation of a metal layer formed by metal CVD.

The second material layer 120L may include a metal oxide with band gap energy of 2.7 eV or more. In some aspects, the second material layer 120L may include a material represented by AMO₃, where A is at least one element selected from La, Ba, Sr, or K, and M is at least one element selected from Al, In, Ga, Ti, Sn, Hf, Ta, or Zr.

For example, the second material layer 120L may include at least one of BaSnO₃, BaHfO₃, BaZrO₃, BaHf₁₋ₓTiₓO₃ (where, 0<x<1), Ba₁₋ₓLaₓSnO₃ (where, 0<x<1), Bi₄Ge₃O₁₂, Al₂O₃, Y₂O₃, La₂O₃, Ga₂O₃, Bi₂O₃, ZrO₂, HfO₂, Ta₂O₅, TiO₂, LaInO₃, LaGaO₃, SrZrO₃, SrHfO₃, SrTaO₇, LaIn₁₋ₓGaₓO₃ (where, 0<x<1), LaGaO₃, SrTiO₃, KTaO₃, HfSiO₄, Ta₃Ti₂Oₓ (where, 0<x<1), or LaAlO₃.

The second material layer 120L is stable even in high-temperature and high-humidity environments and has high carrier mobility. Additionally, carrier movement in the second material layer 120L does not show inelastic collision. Accordingly, an integrated battery comprising the second material layer 120L may have high energy efficiency and excellent heat dissipation characteristics.

According to one or more aspects, carrier mobility in the second material layer 120L may be about 45 cm²/(V·s) or more. According to one or more aspects, carrier mobility in the second material layer 120L may be about 80 cm²/(V·s) or more. According to one or more aspects, carrier mobility in the layer 120L may be about 120 cm²/(V·s) or more. According to one or more aspects, carrier mobility in the second material layer 120L may be about 300 cm²/(V·s) or more.

The second material layer 120L may include a doped semiconductor material, a compound semiconductor, an oxide semiconductor, or a metal alloy. According to one or more aspects, the second material layer 120L may include boron (B)-doped silicon (Si), silicon (Si) doped with one of phosphorus (P) or arsenic (As), zinc (Zn)-doped gallium arsenide (GaAs), gallium arsenide (GaAs) doped with one of silicon (Si) or tellurium (Te), boron (B)-doped germanium (Ge), germanium (Ge) doped with one of phosphorus (P) or antimony (Sb), magnesium (Mg)-doped gallium nitride (GaN), silicon (Si)-doped gallium nitride (GaN), silicon carbide (SiC) doped with one of aluminum (Al) or boron (B), silicon carbide (SiC) doped with one of nitrogen (N) or phosphorus (P), zinc (Zn)-doped indium phosphide (InP), indium phosphide (InP) doped with one of sulfur (S) or silicon (Si), cadmium telluride (CdTe), cadmium sulfide (CdS), tin oxide (SnO), or zinc oxide (ZnO).

The second material layer 120L may be doped with a second conductivity type dopant. The second conductivity type dopant may have a conductivity opposite a conductivity of the first conductivity type dopant. For example, the second conductivity type dopant may be an n-type dopant when the first conductivity type dopant is a p-type dopant, or the second conductivity type dopant may be the p-type dopant when the first conductivity type dopant is the n-type dopant. Accordingly, a pn junction may be formed at an interface between the first material of the substrate 110 and the second material layer 120L of the substrate 110. Additionally, a depletion region due to the pn junction may be formed between the first material of the substrate 110 and the second material layer 120L of the substrate 110.

Referring now to FIGS. 1, 8, and 9, in step P140 of the method of manufacturing an integrated battery of FIG. 1, a radiation source layer 130L may be formed. The radiation source layer 130L may be formed by evaporation, sputtering, CVD, electroplating, or electroless plating. The radiation source layer 130L may fill the recesses 110R. When the radiation source layer 130L is formed by electroplating or electroless plating, a seed layer may be formed between the radiation source layer 130L and the second material layer 120L.

The radiation source layer 130L may include a radioactive isotope. The radiation source layer 130L may be configured to emit radiation. The radiation source layer 130L may include, for example, a radioactive isotope that emits beta rays. The radiation source layer 130L may include at least one of tritium (³H), calcium-45 (⁴⁵Ca), nickel-63 (⁶³Ni), copper-67 (⁶⁷Cu), strontium-90 (⁹⁰Sr), promethium-147 (¹⁴⁷Pm), osmium-194 (¹⁹⁴OS), thulium-171 (¹⁷¹Tm), tantalum-179 (¹⁷⁹Ta), cadmium-109 (¹⁰⁹Cd), germanium-68 (⁶⁸Ge), cerium-159 (¹⁵⁹Ce), or tungsten-181 (¹⁸¹W). The radioactive isotope may emit only beta rays or may emit beta rays along with alpha rays, gamma rays, or the like.

In some aspects, the radiation source layer 130L may include a radioactive isotope that emits alpha rays. For example, the radiation source layer 130L may include one or more of americium-241 (²⁴¹Am), americium-243 (²⁴³Am), polonium-209 (²⁰⁹Po), polonium-210 (²¹⁰Po), plutonium-238 (²³⁸Pu), plutonium-239 (²³⁹Pu), curium-242 (²⁴²Cm), curium-244 (²⁴⁴Cm), curium-249 (²⁴⁹Cm), promethium-147 (¹⁴⁷Pm), uranium-238 (²³⁸U), thorium-232 (²³²Th), radium-226 (²²⁶Ra), bismuth-210 (²¹⁰Bi), neptunium-237 (²³⁷Np), europium-152 (¹⁵²Eu), francium-223 (²²³Fr), astatine-210 (²¹⁰At), protactinium-231 (²³ 1 Pa), einsteinium-253 (²⁵³Es), californium-252 (²⁵²Cf), or berkelium-249 (²⁴⁹Bk). However, aspects of the present disclosure are not limited to these.

Referring now to FIGS. 1, 10, and 11, in step P150 of the method of manufacturing an integrated battery of FIG. 1, a first chemical mechanical polishing (CMP) process may be performed. In one or more aspects, the first CMP process may remove at least a portion of the radiation source layer 130L. In one or more aspects, the first CMP process may remove at least a portion of the metal oxide layer 120L. In some aspects, the first CMP process may remove at least a portion of the substrate 110. In other aspects, the upper surface 110U of the substrate 110 may be an end point of the first CMP process. A change in reflectance inside a CMP chamber or a change in the concentration of a specific chemical component may be used to determine the end point of the CMP process.

The first CMP process may divide the second material layer 120L into a plurality of second material layers 120. The first CMP process may divide the radiation source layer 130L into a plurality of radiation sources 130. An upper surface of each of the plurality of second material layers 120 and an upper surface of each of the plurality of radiation sources 130 may be coplanar with the upper surface 110U of the substrate 110 after the first CMP process.

Referring now to FIGS. 1, 11, and 12, in step P160 of the method of manufacturing an integrated battery of FIG. 1, a second CMP process may be performed. The second CMP process may remove at least a portion of the first material of the substrate 110. In one or more aspects, the second CMP process may remove at least a portion of each of the plurality of second material layers 120. In some aspects, the second CMP process may remove at least a portion of each of the radiation sources 130. In one or more aspects, the plurality of radiation sources 130 may be an end point of the second CMP process. An integrated battery 100 including the substrate 110, the plurality of second material layers 120, and the plurality of radiation sources 130 may be formed by the second CMP process.

The plurality of recesses 110R of FIG. 11 may become a plurality of holes 110H extending to a new lower surface 110L′ of the substrate 110 by the second CMP process. Each of the plurality of holes 110H may penetrate the substrate 110. A lower surface of each of the plurality of second material layers 120 and a lower surface of each of the plurality of radiation sources 130 may be coplanar with the lower surface 110L′.

According to aspects, the substrate 110 may include a plurality of holes 110H having a tapered shape. The plurality of holes 110H may extend in the Z-axis direction perpendicular to the upper surface 110U of the substrate 110. The plurality of holes 110H may penetrate the substrate 110. Each of the plurality of holes 110H may have an opening at an upper surface 110U of the substrate 110 and an opening at the lower surface 110L′ of the substrate 110. In one or more aspects, a cross-sectional area of the opening at the upper surface 110U of the substrate may be greater than a cross-sectional area of the opening at the lower surface 110L′ of the substrate 110.

Each of the plurality of radiation sources 130 may be in a corresponding one of the plurality of holes 110H. Each of the plurality of radiation sources 130 may have a tapered shape.

The plurality of second material layers 120 may be in contact with the substrate 110. In one or more aspects, each of the plurality of second material layers 120 may be in direct contact with the substrate 110. The plurality of second material layers 120 may have polarity opposite to that of the substrate 110. Each of the plurality of second material layers 120 may be between the substrate 110 and one of the plurality of radiation sources 130. In one or more aspects, each of the plurality of second material layers 120 may directly contact the substrate 110 and one of the plurality of radiation sources 130. Each of the plurality of second material layers 120 may have a uniform thickness.

### Third and Fourth Aspects

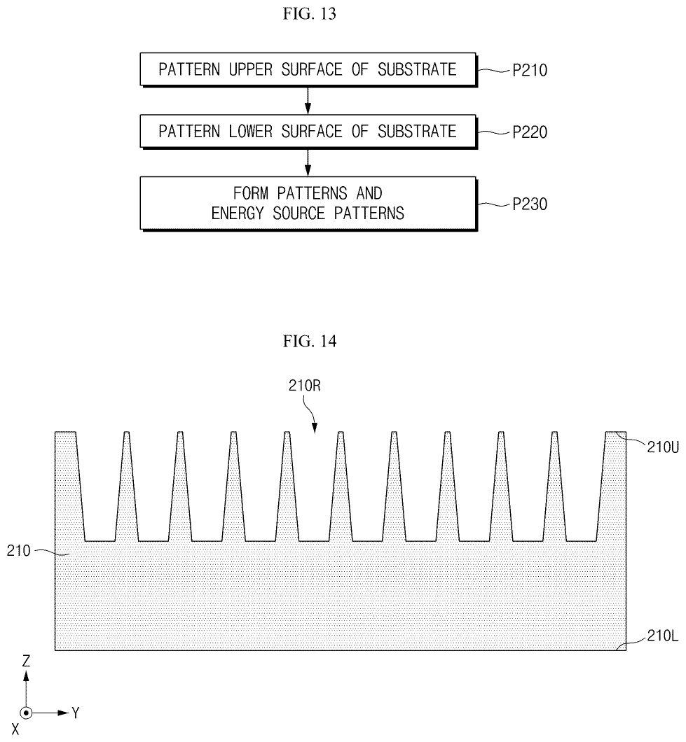

FIG. 13 is a flowchart of a method of manufacturing an integrated battery.

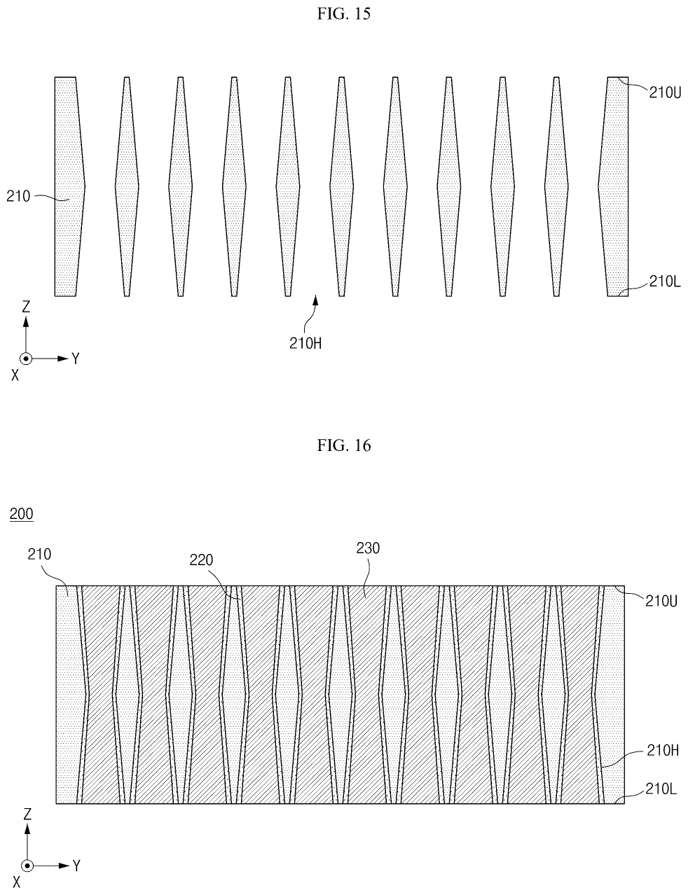

FIGS. 14 to 16 illustrate sequential steps of a method of manufacturing an integrated battery according to aspects.

Referring to FIGS. 13 and 14, in step P210 of the method of manufacturing an integrated battery of FIG. 13, an upper surface 210U of a substrate 210 may be patterned. Patterning the substrate 210 may include removing material from a surface of the substrate 210 to form a plurality of recesses 210R in the substrate 210. The substrate 210 may include any of the materials described above with respect to the substrate 110 of FIG. 2. The substrate 210 may be doped in the same manner as the substrate 110 of FIG. 2. The substrate 210 may be patterned by RIE (reactive ion etching) or ion beam etching.

A plurality of recesses 210R may be formed by etching the substrate 210. In one or more aspects, each of the plurality of recesses 210R may have a circular shape when viewed from above, similar to that described above with respect to the plurality of recesses 110R of FIG. 5. In one or more aspects, each of the plurality of recesses 210R may have a linear shape when viewed from above. The plurality of recesses 210R may be arranged in a matrix, arranged in a honeycomb structure, or form a line-and-space pattern.

Each of the plurality of recesses 210R may have a variable width in the X-axis direction, the Y-axis direction, or both the X and Y-axis directions at different positions along the Z-axis direction. For example, a cross-sectional area of each of the plurality of recesses 210R in a plane extending the X-axis direction and the Y-axis direction may vary along the Z-axis direction. In a specific example, each of the plurality of recesses 210R may have a tapered shape in the Z-axis direction. Each of the plurality of recesses 210R may extend from the upper surface 210U of the substrate 210 in the Z-axis direction into a body of the substrate 210. In one or more aspects, the cross-sectional area of each of the plurality of recesses 210R may decrease as a distance from the upper surface 210U of the substrate 210 increases. A first cross-sectional area of each of the plurality of recesses 210R at a first depth from the upper surface 210U of the substrate 210 may be less than a second cross sectional area of each of the plurality of recesses 210R at a second depth from the upper surface of the substrate 210, which is less than the first depth.

Referring now to FIGS. 13 to 15, in step P220 of the method of manufacturing an integrated battery of FIG. 13, a bottom surface 210L of the substrate 210 may be patterned. The substrate 210 may be patterned by RIE or ion beam etching.

The portion of the lower surface 210L of the substrate 210 that is etched may align with the portion of the upper surface 210U of the substrate 210 that was etched in step P210. In such aspects, the plurality of recesses 210R extending from the upper surface 210U of the substrate 210 may be connected to a plurality of recesses formed in the lower surface 210L of the substrate 210 to form a plurality of holes 210H extending from the upper surface 210U of the substrate 210 to the lower surface 210L of the substrate 210.

In one or more aspects, each of the plurality of holes 210H may have an hourglass shape. In one or more aspects, each of the plurality of holes 210H may have a necked shape.

Referring now to FIGS. 13 and 16, in step P230 of the method of manufacturing an integrated battery of FIG. 13, a plurality of second material layers 220 and a plurality of radiation sources 230 may be formed in the plurality of holes 210H. Accordingly, an integrated battery 200 including the substrate 210, the plurality of second material layers 220, and the plurality of radiation sources 230 may be formed.

In step P230, forming the plurality of second material layers 220 and the plurality of radiation sources 230 may include forming a second material layer by CVD, PVD, or an oxide process, forming an radiation source layer by evaporation, sputtering, CVD, electroplating, or electroless plating, performing a first CMP process using the upper surface 210U of the substrate 210 as an end point, and performing a second CMP process using the lower surface 210L of the substrate 210 as an end point. In one or more aspects, these steps may be performed in a similar manner to the corresponding steps described in more detail hereinabove with respect to the method of manufacturing an integrated battery of FIG. 1.

Each of the plurality of second material layers 220 may include the same material as the second material layer 120L of FIG. 7. Each of the radiation sources 230 may include the same material as the radiation source layer 130L of FIG. 9.

Each of the plurality of second material layers 220 may have a uniform thickness. Each of the plurality of second material layers 220 may be formed conformally in one of the plurality of holes 210H in the substrate 210. In such aspects, the shapes of the plurality of holes 210H may be transferred onto the plurality of second material layers 220.

The plurality of radiation sources 230 may be in the plurality of holes 210H. Each of the plurality of radiation sources 230 may fill a space defined by one of the plurality of second material layers 220. One of the plurality of second material layers 220 may be interposed between one of the plurality of radiation sources 230 and the substrate 210. In one or more aspects, one of the plurality of second material layers 220 may directly contact one of the radiation sources 230 and the substrate 210. In one or more aspects, each of the plurality of radiation sources 230 may have an hourglass shape. In one or more aspects, each of the plurality of radiation sources 230 may have a necked shape.

### Fifth and Sixth Aspects

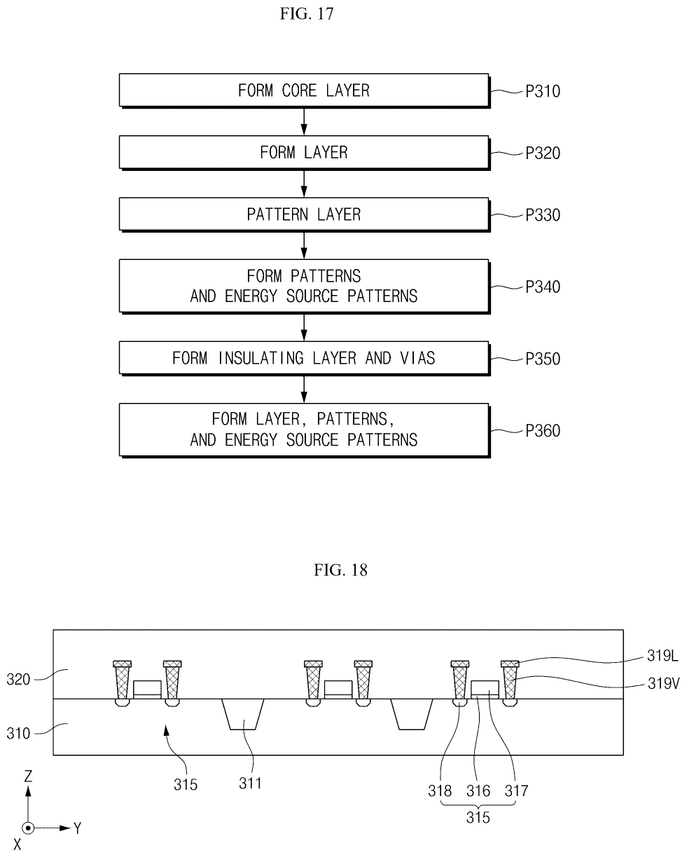

FIG. 17 is a flowchart of a method of manufacturing an integrated battery.

FIGS. 18 to 21 are cross-sectional views illustrating sequential steps of a method of manufacturing an integrated battery according to aspects.

FIG. 22 is a plan view illustrating a step of a method of manufacturing an integrated battery according to aspects.

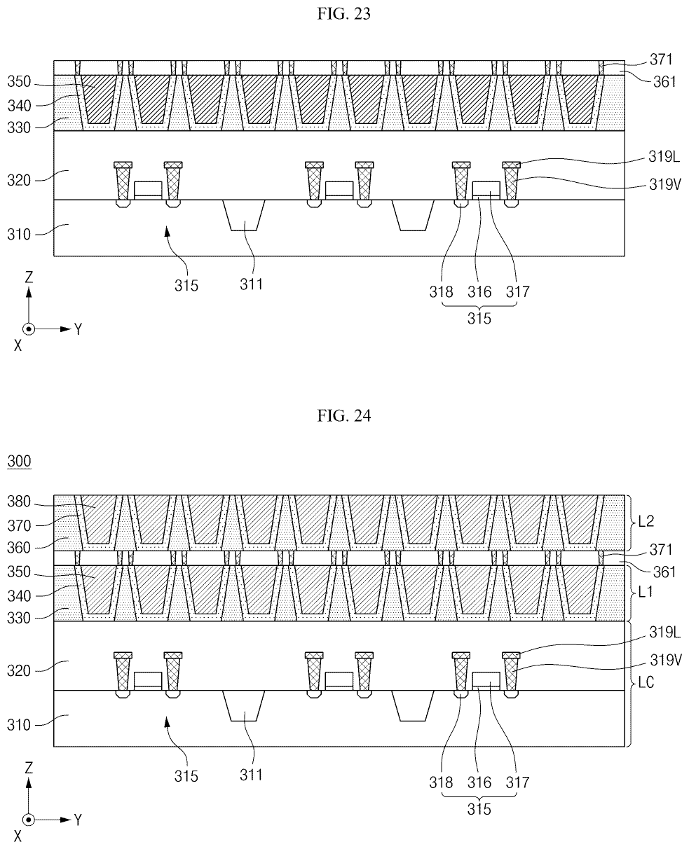

FIG. 23 is a cross-sectional view taken along line 22I-22I′ of FIG. 22.

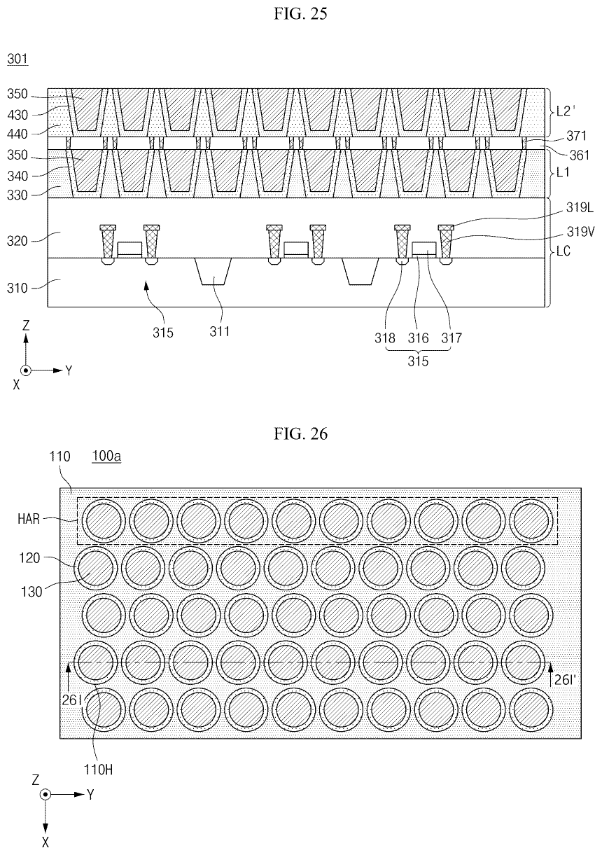

FIG. 24 is a cross-sectional view illustrating a step of a method of manufacturing an integrated battery according to aspects.

Referring now to FIGS. 17 and 18, in step P310 of the method of manufacturing an integrated battery of FIG. 17, a core layer LC may be formed. Forming of the core layer LC may include forming an isolation film 311 on a core layer substrate 310; forming a p-well region and an n-well region on the core layer substrate 310 by an ion implantation process using a photoresist pattern; forming peripheral transistors 315; and providing an insulating layer 320 comprising conductive vias 319V and conductive lines 319L.

In one or more aspects, the core layer substrate 310 may include a semiconductor material such as silicon, germanium or silicon-germanium, and the core layer substrate 310 may further include an epitaxial layer, a silicon-on-insulator (SOI) layer, a germanium-on-insulator (GOI) layer, a semiconductor-on-insulator (SeOI) layer or the like.

Each of the peripheral transistors 315 may include a gate oxide layer 316, a gate electrode 317, and source/drain regions 318. Each of the peripheral transistors 315 may be formed through a component metal-oxide-semiconductor (CMOS) logic process.

In one or more aspects, the CMOS logic process may include forming the gate oxide film 316, forming the gate electrode 317 that includes polysilicon or metal, and forming the source/drain regions 318 through ion implantation. Although not depicted in FIG. 18, gate spacers may be further formed after the formation of the gate electrode 317.

Each of the conductive vias 319V and the conductive lines 319L may include a conductive material. Each of the conductive vias 319V and the conductive lines 319L may include copper, but aspects of the present disclosure are not limited thereto. Each of the conductive vias 319V and the conductive lines 319L may include one or more of tungsten, tantalum, cobalt, nickel, tungsten silicide, tantalum silicide, cobalt silicide, or nickel silicide. Each of the conductive vias 319V and the conductive lines 319L may include polysilicon.

Each of the conductive vias 319V may extend in the Z-axis direction. The conductive vias 319V may be embedded in an insulating layer 320. The conductive vias 319V may be connected to the peripheral transistors 315 or the conductive lines 319L.

Each of the conductive lines 319L may extend in a horizontal direction. For example, each of the conductive lines 319L may extend in the X-axis direction and/or the Y-axis direction. The conductive lines 319L may be embedded in the insulating layer 320. The conductive lines 319L may be connected to the conductive vias 319V.

The insulating layer 320 may include at least one of silicate (e.g., TEOS), silicon nitride (SiN), hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, or aluminum oxide.

The insulating layer 320 may include a plurality of insulating layers that are formed sequentially. For example, in each layer, an insulating layer may be formed to form conductive vias 319V, and in each layer, an insulating layer may be formed to form conductive lines 319L.

Referring to FIGS. 17 and 19, in step P320 of the method of manufacturing an integrated battery of FIG. 17, a first substrate 330 may be formed. The first substrate 330 may comprise a first material. The first substrate 330 may be formed by CVD or epitaxial growth. The first substrate 330 may be doped with a first dopant. In one or more aspects, the first dopant may be introduced into the first substrate 330 during the growth of the first substrate 330. In one or more aspects, the first substrate 330 may be doped with the first dopant by ion implantation and diffusion after the first substrate 330 is formed.

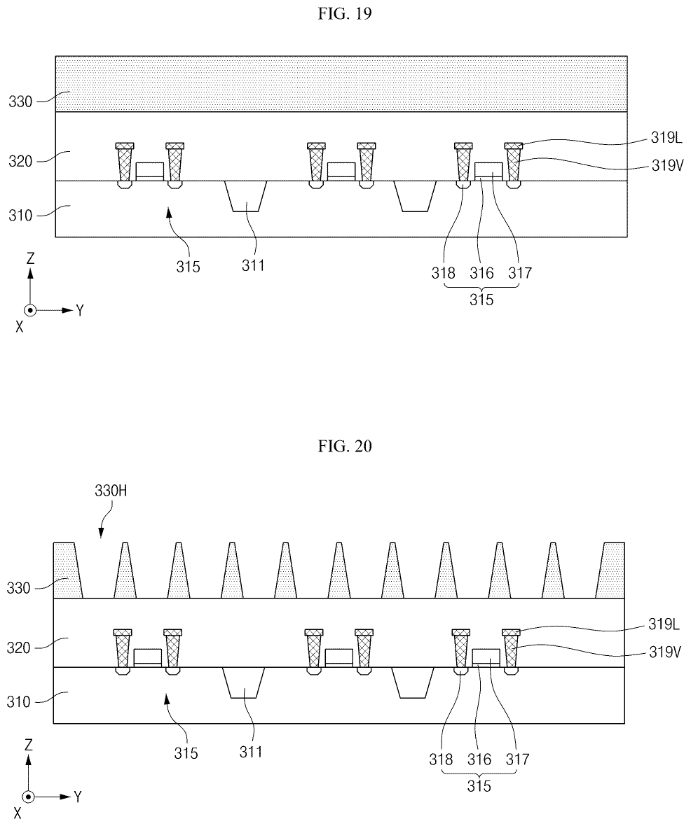

Referring now to FIGS. 17 and 20, in step P330 of the method of manufacturing an integrated battery of FIG. 17, the first substrate 330 may be etched to form a plurality of first holes 330H. The first substrate 330 may be etched by RIE or ion beam etching. The first substrate 330 may be etched by anisotropic wet etching.

The first substrate 330 may be etched to form a plurality of holes 330H exposing the insulating layer 320. Each of the plurality of first holes 330H may have a circular shape or a linear shape in a plane normal to the Z-axis direction, similar to that described above with respect to the plurality of recesses 110R of FIG. 5. The plurality of first holes 330H may be arranged in a matrix, such as arranged in a honeycomb structure, or may form a line-and-space pattern.

Each of the plurality of first holes 330H may have a variable width in the X-axis direction, the Y-axis direction, or both the X and Y-axis directions at different positions along the Z-axis direction. For example, a cross-sectional area of each of the plurality of first holes 330H in a plane extending the X-axis direction and the Y-axis direction may vary along the Z-axis direction. In a specific example, each of the plurality of first holes 330H may have a tapered shape in the Z-axis direction. Each of the plurality of first holes 330H may extend from the upper surface 210U of the first substrate 330 in the Z-axis direction into a body of the first substrate 330. In one or more aspects, the cross-sectional area of each of the plurality of first holes 330H may decrease as a distance from the upper surface 210U of the first substrate 330 increases. A first cross-sectional area of each of the plurality of first holes 330H at a first depth from the upper surface 210U of the first substrate 330 may be less than a second cross-sectional area of each of the plurality of first holes 330H at a second depth from the upper surface 210U of the first substrate 330 when the second depth is less than the first depth.

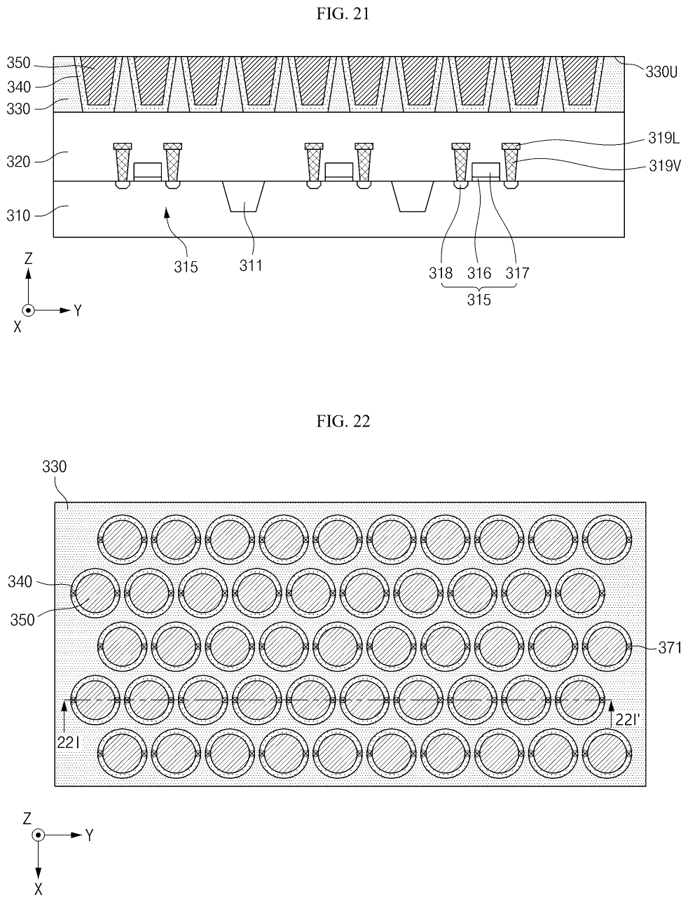

Referring now to FIGS. 17 and 21, in step P340 of the method of manufacturing an integrated battery of FIG. 17, a plurality of second material layers 340 and a plurality of first radiation sources 350 may be formed.

The forming of the plurality of second material layers 340 and the plurality of radiation sources 350 may include forming a second material layer by CVD, PVD, or an oxidation process, forming a radiation source layer by evaporation, sputtering, CVD, electroplating, or electroless plating, and performing a CMP process using an upper surface of the first substrate 330 as an end point. In one or more aspects, these steps may be performed in a similar manner to the corresponding steps described in more detail hereinabove with respect to the method of manufacturing an integrated battery of FIG. 1.

The plurality of second material layers 340 may partially fill the plurality of first holes 330H. Each of the plurality of second material layers 340 may have a uniform thickness. Each of the plurality of second material layers 340 may be formed conformally in one of the plurality of first holes 330H in the first substrate 330. Each of the plurality of second material layers 340 may have a cup shape.

Each of the plurality of second material layers 340 may comprise a second material. The second material may be doped with a second dopant with polarity opposite to that of the first dopant. Accordingly, the polarity of each of the second material layers 340 may be opposite to that of the first substrate 330. In such aspects, a pn junction and a depletion region may be formed at an interface between the plurality of second material layers 340 and the first substrate 330. The first substrate 330 and each of the plurality of second material layers 340 may each individually comprise one of a doped semiconductor material, a compound semiconductor, an oxide semiconductor, or a metal alloy.

According to aspects, the first substrate 330 may include silicon (Si) doped with boron (B), and each of the plurality of second material layers 340 may include silicon (Si) doped with phosphorus (P) or arsenic (As). The first substrate 330 may include silicon (Si) doped with phosphorus (P) or arsenic (As), and each of the plurality of second material layers 340 may include silicon (Si) doped with boron (B).

According to aspects, the first substrate 330 may include gallium arsenic (GaAs) doped with zinc (Zn), and each of the plurality of second material layers 340 may include gallium arsenic (GaAs) doped with silicon (Si) or tellurium (Te). The first substrate 330 may include gallium arsenic (GaAs) doped with silicon (Si) or tellurium (Te), and each of the plurality of second material layers 340 may include gallium arsenic (GaAs) doped with zinc (Zn).

According to aspects, the first substrate 330 may include germanium (Ge) doped with boron (B), and each of the plurality of second material layers 340 may include germanium (Ge) doped with phosphorus (P) or antimony (Sb). The first substrate 330 may include germanium (Ge) doped with phosphorus (P) or antimony (Sb), and each of the plurality of second material layers 340 may include germanium (Ge) doped with boron (B).

According to aspects, the first substrate 330 may include gallium nitride (GaN) doped with magnesium (Mg), and each of the plurality of second material layers 340 may include gallium nitride (GaN) doped with silicon (Si). The first substrate 330 may include gallium nitride (GaN) doped with silicon (Si), and each of the plurality of second material layers 340 may include gallium nitride (GaN) doped with magnesium (Mg).

According to aspects, the first substrate 330 may include silicon carbide (SiC) doped with aluminum (Al) or boron (B), and each of the plurality of second material layers 340 may include silicon carbide (SiC) doped with nitrogen (N) or phosphorus (P). The first substrate 330 may include silicon carbide (SiC) doped with nitrogen (N) or phosphorus (P), and each of the plurality of second material layers 340 may include silicon carbide (SiC) doped with aluminum (Al) or boron (B).

According to aspects, the first substrate 330 may include indium phosphide (InP) doped with zinc (Zn), and each of the plurality of second material layers 340 may include indium phosphide (InP) doped with sulfur (S) or silicon (Si). The first substrate 330 may include indium phosphide (InP) doped with sulfur (S) or silicon (Si), and each of the plurality of second material layers 340 may include indium phosphide (InP) doped with zinc (Zn).

According to aspects, the first substrate 330 may include cadmium telluride (CdTe), and each of the plurality of second material layers 340 may include cadmium sulfide (CdS). The first substrate 330 may include cadmium sulfide (CdS), and each of the plurality of second material layers 340 may include cadmium telluride (CdTe).

According to aspects, the first substrate 330 may include tin oxide (SnO), and each of the plurality of second material layers 340 may include zinc oxide (ZnO). The first substrate 330 may include zinc oxide (ZnO), and each of the plurality of second material layers 340 may include tin oxide (SnO).

Each of the first radiation sources 350 may include the same material as the radiation source layer 130L of FIG. 9 described hereinabove. Each of the plurality of first radiation sources 350 may have a tapered shape. Each of the plurality of second material layers 340 may be interposed between the first substrate 330 and one the plurality of first radiation sources 350. In one or more aspects, each of the plurality of second material layers 340 may directly contact the first substrate 330. In one or more aspects, each of the plurality of second material layers 340 may directly contact one of the plurality of first radiation sources 350.

Referring now to FIGS. 7, 22, and 23, in step P350 of the method of manufacturing an integrated battery of FIG. 17, an insulating layer 361 and a plurality of vias 371 may be formed. The insulating layer 361 may include one of the materials included in the insulating layer 320 described hereinabove. Each of the plurality of vias 371 may extend in the Z-axis direction. The plurality of vias 371 may be in contact with the plurality of second material layers 340 of the first battery layer. Each of the plurality of vias 371 may include a conductive material. Each of the plurality of vias 371 may include a metal. Each of the plurality of vias 371 may include at least one of aluminum (Al), copper (Cu), tungsten (W), or titanium (Ti). Based on the above description, those of ordinary skill in the art will be able to easily derive an aspect in which a wiring structure including two or more layers of vias and one or more layers of patterns is embedded in the insulating layer 361.

In one or more aspects, forming of the plurality of vias 371 may include depositing an insulating material to form an insulating material layer, etching the insulating material layer to form the insulating layer 361 including a plurality of via holes to expose upper surfaces of the plurality of second material layers 340, providing a conductive material layer to fill the plurality of via holes, and separating the conductive material layer into the plurality of vias 371 through a planarization process.

Referring now to FIGS. 17 and 24, in step P360 of the method of manufacturing an integrated battery of FIG. 17, a second substrate 360, a plurality of fourth material layers 370, and a plurality of second radiation sources 380 may be formed. In step P360, forming of the second substrate 360, the plurality of fourth material layers 370, and the plurality of second radiation sources 380 may include forming the second substrate 360 as described in step P320 with respect to the first substrate 330, etching the second substrate 360 as described in step P330 with respect to the first substrate 330, and forming the plurality of fourth material layers 370 and the plurality of second radiation sources as described in step P340 with respect to the plurality of second material layers 340 and the plurality of first radiation sources 350. Accordingly, an integrated battery 300 including the core layer LC, a first battery layer L1, and a second battery layer L2 may be formed. The first battery layer L1 may be on the core layer LC. The insulating layer 361 may be interposed between the first battery layer L1 and the second battery layer L2.

The core layer LC may include a plurality of transistors 315 on the substrate 310. An additional passive element may be formed on the substrate 310. For example, the core layer LC may include a voltage regulator configured to adjust resulting voltages of the first battery layer L1 and the second battery layer L2. The core layer LC may include a linear voltage regulator, a buck regulator, a booster regulator, or a buck-boost regulator.

The second substrate 360, the plurality of fourth material layers 370, and the plurality of second radiation sources 380 of the second battery layer L2 may be provided by substantially the same method as the first substrate 330, the plurality of second material layers 340, and the plurality of first radiation sources 350 of the first battery layer L1, respectively. The second substrate 360, the plurality of fourth material layers 370, and the plurality of second radiation sources 380 of the second battery layer L2 may be substantially the same as the first substrate 330, the plurality of fourth material layers 340, and the plurality of first radiation sources 350 of the first battery layer L1, respectively.

Each of the plurality of second material layers 340 of the first battery layer L1 may be connected to the second substrate 330 of the second battery layer L2 via the plurality of vias 371. Accordingly, the first battery layer L1 may be connected to the second battery layer L2 in series.

Each of the first battery layer L1 and the second battery layer L2 of the integrated battery 300 may be a unit battery layer. According to aspects, unit battery layers may be connected in series by performing a semiconductor manufacturing process on one substrate, thereby increasing a voltage to be output from the integrated battery 300. Based on the above description, those of ordinary skill in the art will be able to easily derive an integrated battery including three or more unit battery layers connected in series.

### Seventh Aspect

FIG. 25 is a diagram illustrating an integrated battery 301 according to an aspect.

Referring to FIG. 25, the integrated battery 301 may include a core layer LC, a first battery layer L1, and a second battery layer L2′. The core layer LC and the first battery layer L1 are substantially the same as those described above with reference to FIGS. 17 to 23. Thus redundant description thereof is omitted here.

The second battery layer L2′ may include a plurality of fourth material layers 430, a second substrate 440, and a plurality of second radiation source patterns 380. In the second battery layer L2′, the second substrate 440 may have substantially the same shape as the first substrate 330 of the first battery layer L1 but have polarity opposite to that of the first substrate 330 of the first battery layer L1. Each of the plurality of fourth material layers 430 may have substantially the same shape as each of the plurality of second material layers 340 of the first battery layer L1 but may have polarity opposite to that of each of the plurality of second material layers 340 of the first battery layer L1. The polarity of each of the plurality of second material layers 430 may be opposite to that of the second substrate 440.

In the aspect depicted in FIG. 25, each of the plurality of second material layers 340 of the first battery layer L1 may be connected to the second substrate 440 of the second battery layer L2′ by a plurality of vias 371. Accordingly, the first battery layer L1 may be connected to the second battery layer L2′ in parallel.

Each of the first battery layer L1 and the second battery layer L2′ of the integrated battery 301 may be a unit battery layer. According to aspects, unit battery layers may be connected in parallel by performing a semiconductor manufacturing process on one substrate, thereby increasing a voltage to be output from the integrated battery 301. Based on the above description, those of ordinary skill in the art will be able to easily derive an integrated battery including three or more unit battery layers connected in parallel.

### Eighth Aspect

FIG. 26 is a plan view of an integrated battery 100a according to aspects.

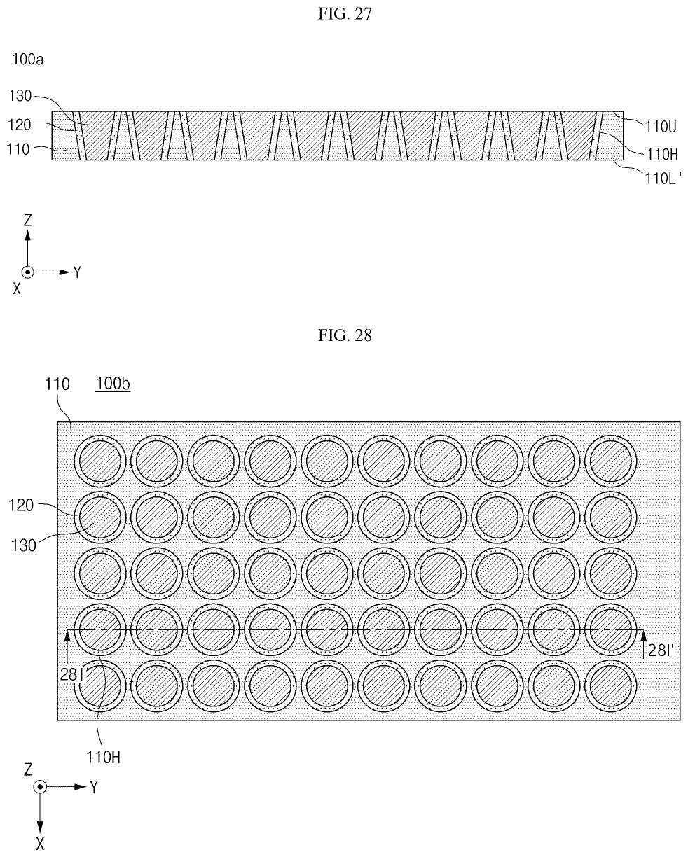

FIG. 27 is a cross-sectional view taken along line 26I-26I′ of FIG. 26.

Referring to FIGS. 26 and 27, the integrated battery 100a may include a substrate 110, a plurality of second material layers 120, and a plurality of radiation sources 130. The substrate 110, the plurality of second material layers 120, and the plurality of radiation sources 130 are substantially the same as those described above with reference to FIGS. 1 to 12 except for an arrangement of a plurality of holes 110H in the substrate 110. Thus, redundant description thereof is omitted here.

The plurality of holes 110H of FIGS. 26 and 27 may be arranged in a non-honeycomb structure, unlike the plurality of holes 110H of FIG. 12 that are arranged in the honeycomb structure. At least some of the centers of the plurality of holes 110H may be offset from positions for forming the honeycomb structure in the X-axis direction, in the Y-axis direction, or in both the X-axis direction and the Y-axis direction. In one or more aspects, a portion of the plurality of holes 110H may be arranged in an array. As described herein, a portion of the plurality of holes 110H are in an array when the portion of the plurality of holes are aligned in the X-axis direction or the Y-axis direction. For example, a portion of the plurality of holes 110H in hole array HAR are aligned along the Y-axis direction. When the integrated battery 100a comprises arrays of the plurality of holes 110H aligned along the Y-axis direction, neighboring hole arrays HARs in the X-axis direction may be staggered such that holes 110H in a first hole array are not aligned in the X-axis direction with holes 110H in an second hole array that is adjacent to the first hole array in the X-axis direction. In such aspects, the plurality of holes 110H may be staggered or arranged in a zigzag fashion along the X-axis direction.

The plurality of second material layers 120 and the plurality of radiation sources 130 may fill the plurality of holes 110H together, as previously described. Thus, the description of the arrangement of the plurality of holes 110H may also apply to the plurality of second material layers 120 and the plurality of radiation sources 130.

### Ninth Aspect

FIG. 28 is a plan view of an integrated battery 100b according to an aspect.

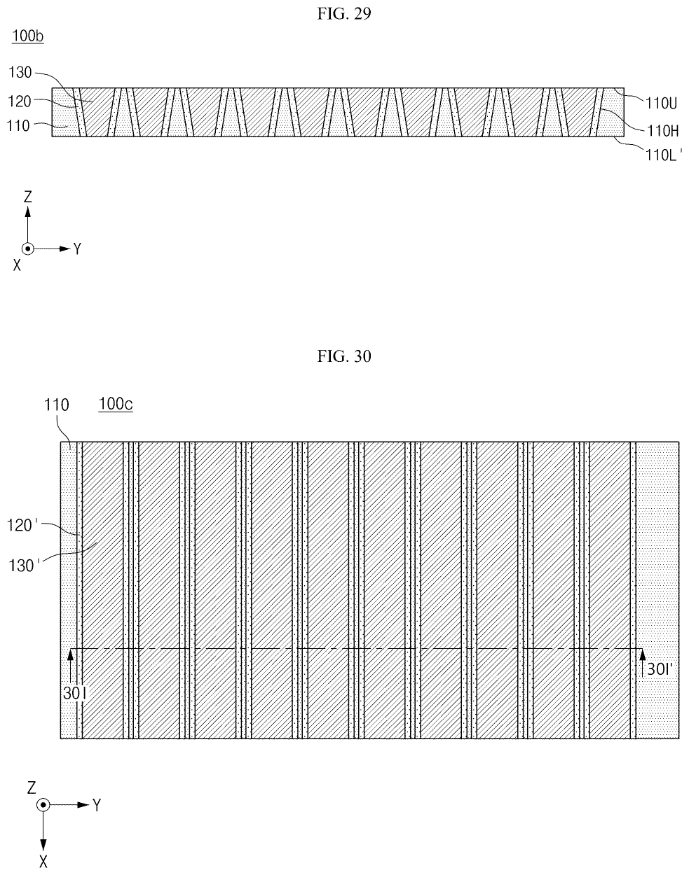

FIG. 29 is a cross-sectional view taken along line 28I-28I′ of FIG. 28.

Referring to FIGS. 28 and 29, the integrated battery 100b may include a substrate 110, a plurality of second material layers 120, and a plurality of radiation sources 130. The substrate 110, the plurality of second material layers 120, and the plurality of radiation sources 130 are substantially the same as those described above with reference to FIGS. 1 to 12, except for an arrangement of a plurality of holes 110H. Thus, redundant description thereof is omitted here.

In the present aspect, the plurality of holes 110H may be arranged in a matrix, unlike the plurality of holes 110H of FIG. 12 that are arranged in the honeycomb structure. As described herein, a plurality of holes 110H are aligned in a matrix when the plurality of holes 110H are aligned in the X-axis direction and the Y-axis direction. In the present aspect, the plurality of holes 110H may be aligned in the X-axis direction. In the present aspect, the plurality of holes 110H may be aligned in the Y-axis direction.

The plurality of second material layers 120 and the plurality of radiation sources 130 fill the plurality of holes 110H together, and thus, the description of the arrangement of the plurality of holes 110H may also apply to the plurality of second material layers 120 and the plurality of radiation sources 130.

### Tenth Aspect

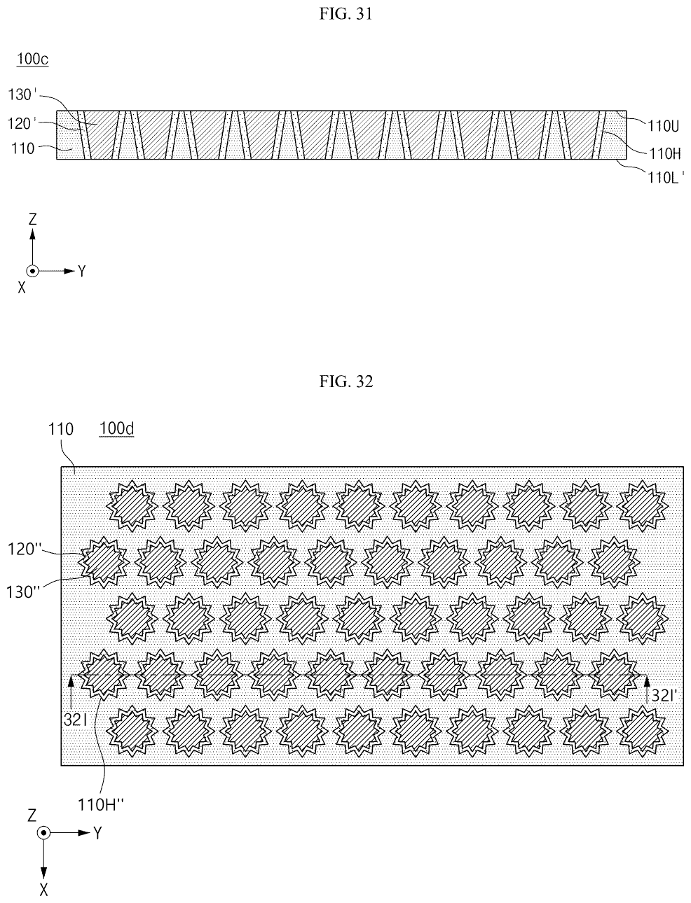

FIG. 30 is a plan view of an integrated battery 100c according to an aspect.

FIG. 31 is a cross-sectional view taken along line 30I-30I′ of FIG. 30.

Referring to FIGS. 30 and 31, the integrated battery 100c may include a substrate 110, a plurality of second material layers 120′, and a plurality of radiation sources 130′. The substrate 110, the plurality of second material layers 120′, and the plurality of radiation sources 130′ are substantially the same as those described above with reference to FIGS. 1 to 12, except for a change in a shape of a plurality of holes 110H′. Thus, redundant description thereof is omitted here.

In the present aspect, the plurality of holes 110H′ may have a linear shape, unlike the circular shape of the plurality of holes 110H of FIG. 12. In one or more aspects, holes having a linear shape may be elongated along a direction perpendicular to the Z-axis direction. In one or more aspects, holes having a linear shape may be elongated along the X-axis direction or along the Y-axis direction. For example, each of the plurality of holes 110H′ may be elongated along the X-axis direction, as depicted in FIG. 30. In one or more aspects, the plurality of holes 110H′ may have a line-and-space structure. For example, the plurality of holes 110H′ may be spaced apart from each other in the Y-axis direction.

Each of the plurality of second material layers 120′ may be on a sidewall of one of the plurality of holes 110H′. For example, each of the plurality of second material layers 120′ may extend along the X-axis direction. Each of the plurality of second material layers 120′ may have a uniform thickness.

The plurality of radiation sources 130′ may fill the plurality of holes 110H′. For example, each of the plurality of radiation sources 130′ may be elongated along the X-axis direction. Each of the plurality of radiation sources 130′ may have a linear shape extending along the X-axis direction. Each of the plurality of radiation sources 130′ may have a tapered shape in the Z-axis direction.

### Eleventh Aspect

FIG. 32 is a plan view of an integrated battery 100d according to an aspect.

FIG. 33 is a cross-sectional view taken along line 32I-32I′ of FIG. 32.

Referring to FIGS. 32 and 33, the integrated battery 100d may include a substrate 110, a plurality of second material layers 120″, and a plurality of radiation sources 130″. The substrate 110, the plurality of second material layers 120″, and the plurality of radiation sources 130″ are substantially the same as those described above with reference to FIGS. 1 to 12, except for a change in a shape of a plurality of holes 110H″. Thus, redundant description thereof is omitted here.

According to aspects, an additional etching process may be performed to modify the plurality of holes 110H″ before forming a material layer, such as the second material layer 120L as described above with respect to FIG. 7, to form the plurality of second material layers 120″. The additional etching process may be, for example, a wet etching process.

According to aspects, each of the plurality of holes 110H″ may have a roughened circular shape along their perimeters when viewed from above after the additional etching process. According to one or more aspects, each of the plurality of holes 110H″ may have a star shape when viewed from above after the additional etching process.

According to aspects, each of the second material layers 120″ may have a roughened ring shape when viewed from above. For example, the second material layer 120″ may be conformal to the hole 110 H″ and may have a substantially similar roughened surface. In one or more aspects, each of the second material layers 120″ may have a hollow star shape when viewed from above.

According to aspects, each of the plurality of radiation sources 130″ may have a roughened circular shape along their perimeters when viewed from above. According to aspects, each of the plurality of radiation sources 130″ may have a star shape when viewed from above.

According to aspects, the roughened shapes of the plurality of holes 110H″, the second material layers 120″, and the plurality of radiation sources 130″, when viewed from above, may follow tapered profiles along the Z-axis direction. In some aspects, those tapered profiles may be smooth along the Z-axis direction, such that interfaces between the abutting materials define straight lines in a YZ plane, normal to the X-axis direction. In other aspects, as shown in FIG. 33, the tapered profiles may be roughened along the Z-axis direction.

According to aspects, an interface between the substrate 110 and each of the plurality of second material layers 120″ may be roughened. According to aspects, an interface between the plurality of patterns 120″ and the plurality of radiation sources 130″ may be roughened. In such aspects, the surface area over which the substrate 110 contacts each of the plurality of second material layers 120″ may be increased, and the surface area over which each of the plurality of the second material layers 120″ contacts each of the plurality of radiation sources 130″ may be increased.

### Twelfth and Thirteenth Aspects

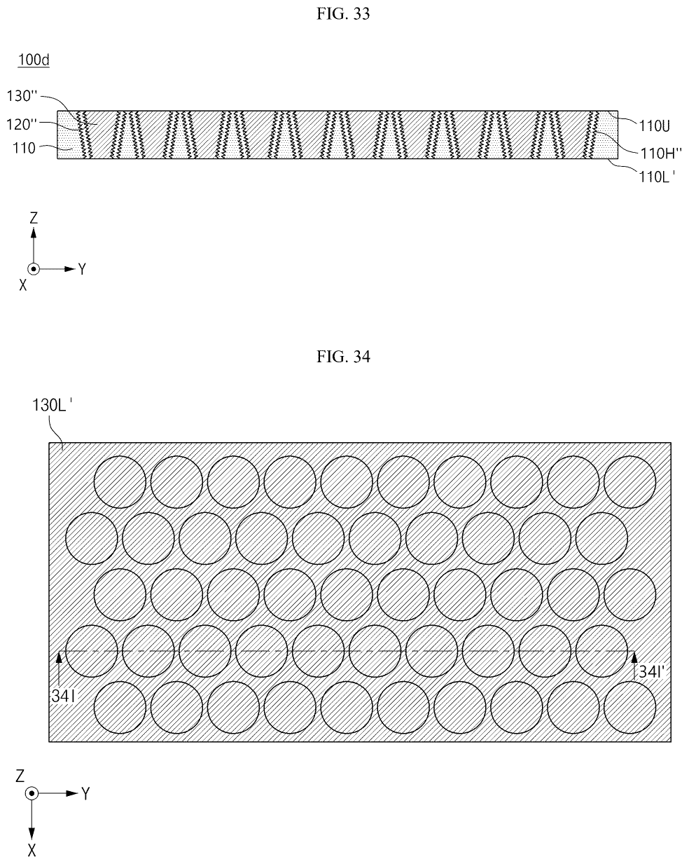

FIG. 34 is a plan view illustrating a step of a method of manufacturing an integrated battery according to an aspect.

FIG. 35 is a cross-sectional view taken along line 34I-34I′ of FIG. 34.

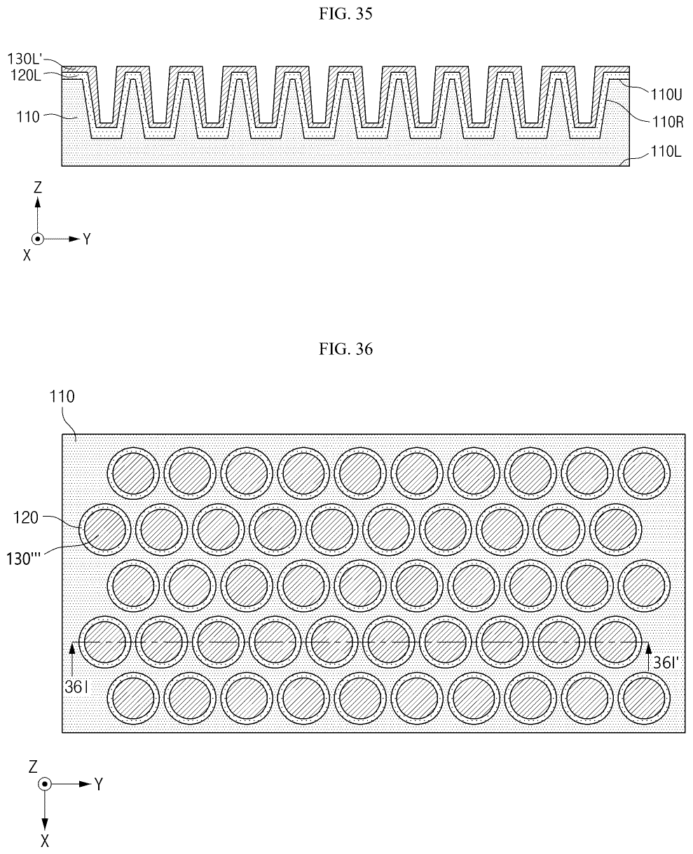

FIG. 36 is a plan view illustrating a step of a method of manufacturing an integrated battery according to an aspect.

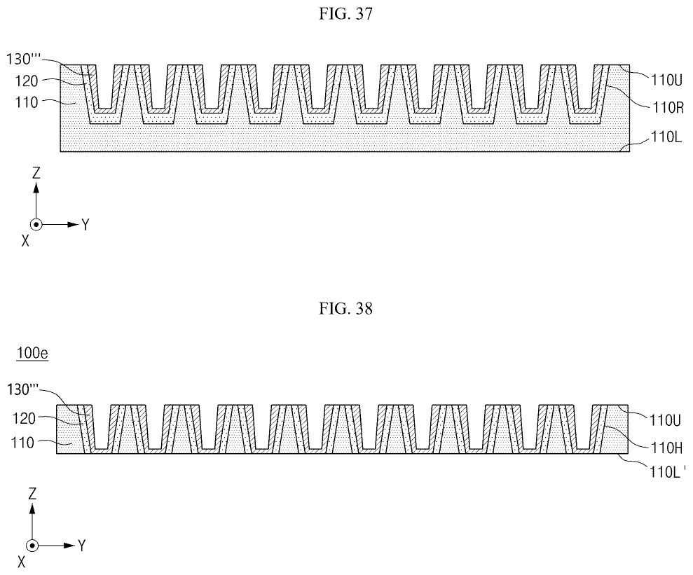

FIG. 37 is a cross-sectional view taken along line 36I-36I′ of FIG. 36.

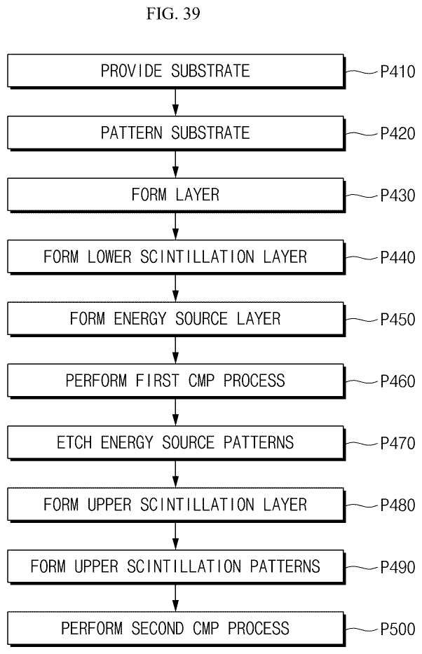

FIG. 38 is a cross-sectional view of an integrated battery according to an aspect.

Referring to FIGS. 34 and 35, a radiation source layer 130L′ may be formed. In the present aspect, the radiation source layer 130L′ may partially fill each of the plurality of recesses 110R, unlike a radiation source layer 130L that substantially fills each of the plurality of recesses 110R. The radiation source layer 130L′ may have a uniform thickness. The radiation source layer 130L′ may have a conformal shape.

Referring now to FIGS. 36 and 37, a first CMP process may be performed. The radiation source layer 130L′ may be divided into a plurality of radiation sources 130′″ by the first CMP process.

A plurality of second material layers 120 are substantially the same as those described above with respect to FIGS. 10 and 11. Thus redundant description thereof is omitted here.

Referring now to FIG. 38, a second CMP process may be performed. The plurality of radiation sources 130′″ may be an end point of the second CMP process. An integrated battery 100e including the substrate 110, the plurality of second material layers 120, and the plurality of radiation sources 130′″ may be formed by the second CMP process. According to aspects, the plurality of radiation sources 130′″ may have a cup shape. According to aspects, a space defined by the plurality of cup-shaped radiation sources 130′″ may be filled by an additional material. The additional material may be any suitable material for use in the integrated battery 100e.

### Fourteenth and Fifteenth Aspects

FIG. 39 is a flowchart of a method of manufacturing an integrated battery according to an aspect.

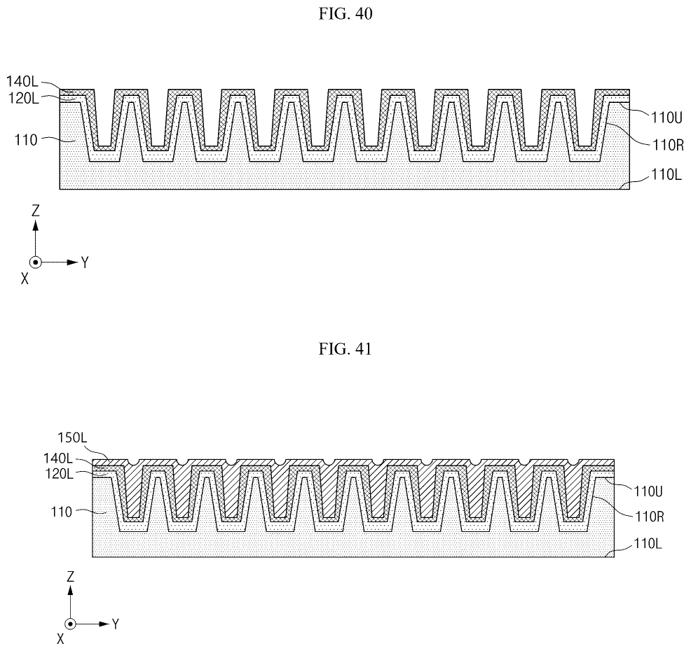

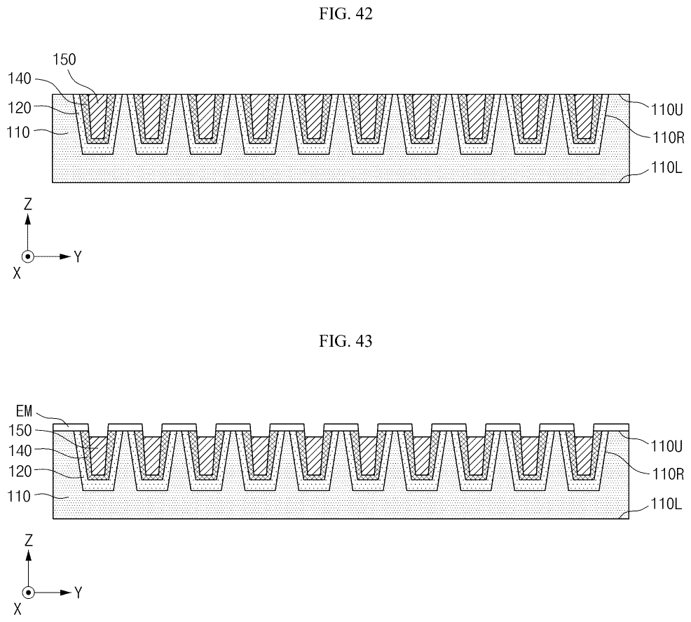

FIGS. 40 to 46 are cross-sectional views illustrating sequential steps of a method of manufacturing an integrated battery according to an aspect.

Referring to FIGS. 39 and 40, the step of providing a substrate 110 in step P410 of the method of manufacturing an integrated battery illustrated in FIG. 39 is substantially the same as the step of providing of the substrate 110 in previously described step P110 of a method of manufacturing an integrated battery. The step of patterning the substrate 110 in step P420 is substantially the same as the step of patterning of the substrate 110 in previously described step P120. The step of forming a second material layer 120L in step P430 is substantially the same as the step of forming of the second material layer 120L in previously described step P130. In this aspect, a shape and arrangement of the recesses 110R may be the same as those described with respect to FIG. 4, 26, 28, 30, or 32.

In the present aspects, in step P440, a lower scintillation layer 140L may be formed. The lower scintillation layer 140L may be formed by a deposition process such as CVD. The lower scintillation layer 140L may have a uniform thickness. The lower scintillation layer 140L may have a conformal shape. The lower scintillation layer 140L may comprise a material that emits photons in response to high-energy radiation. The scintillation layer 140L may include at least one of Ba₂Ca(BO₃)₂, BaHfO₃, BaI₂:Ce, BeO, BaF₂, BaMgF₄, Cs₂LiLuCi₆:Ce, K₂YF₅, KCaF₃ or YI₃:Ce but is not limited thereto. Various examples of the lower scintillation layer 140L are disclosed in the Berkeley Lab Inorganic Scintillator Laboratory found at: https://scintillator.lbl.gov/inorganic-scintillator-library/.

Referring now to FIGS. 39 and 41, in step P450 of the method of making an integrated battery illustrated in FIG. 39, a radiation source layer 150L may be formed. The radiation source layer 150L may fill the recesses 110R. The radiation source layer 150L may be formed by evaporation, sputtering, CVD, electroplating, or electroless plating. When the radiation source layer 150L is formed by electroplating or electroless plating, a seed layer may be formed between the radiation source layer 150L and the lower scintillation layer 140L.

The radiation source layer 150L may comprise a radioactive isotope that emits only alpha rays, or may include a radioactive isotope that emits both alpha rays and radiation other than alpha rays, such as beta rays or gamma rays. The radiation source layer 150L may include at least one of neodymium-144 (¹⁴⁴Nd), samarium-147 (¹⁴⁷Sm), terbium-158 (¹⁵⁸Tb), tellurium-104 (¹⁰⁴Te), bismuth-212 (²¹²Bi), astatine-210 (²¹⁰At), astatine-211 (²¹¹At), radon-222 (²²²Rn), francium-223 (²²³Fr), radium-224 (²²⁴Ra), radium-226 (²²⁶Ra), actinium-225 (²²⁵Ac), actinium-227 (²²⁷Ac), thorium-228 (²²⁸Th), thorium-230 (²³⁰Th), thorium-232 (²³²Th), protactinium-231(²³¹ Pa), uranium-234 (²³⁴U), uranium-235 (²³⁵U), uranium-238 (²³⁸U), neptunium-237 (²³⁷Np), plutonium-238 (²³⁸Pu), plutonium-239 (²³⁹Pu), plutonium-240 (²⁴⁰Pu), plutonium-241 (²⁴¹Pu), americium-241 (²⁴¹Am), americium-243 (²⁴³Am), curium-242 (²⁴²Cm), curium-243 (²⁴³Cm), curium-244 (²⁴Cm), curium-245 (²⁴⁵Cm), berkelium-247 (²⁴⁷Bk), berkelium-249 (²⁴⁹Bk), californium-249 (²⁴⁹Cf), californium-250 (²⁵⁰Cf), californium-251 (²⁵¹Cf), californium-252 (²⁵²Cf), einsteinium-252 (²⁵²Es), einsteinium-253 (²⁵³Es), fermium-257 (²⁵⁷Fm), mandellevium-258 (²⁵⁸Md), nobelium-255 (²⁵⁵No), laurencium-260 (²⁶⁰Lr), polonium-208 (²⁰⁸Po), polonium-210 (²¹⁰Po), or polonium-212 (²¹²Po).

Referring now to FIGS. 39, 41, and 42, in P460, a first CMP process may be performed. The upper surface 110U of the substrate 110 may be an end point of the first CMP process.

By the first CMP process, the second material layer 120L may be divided into a plurality of second material layers 120. By the first CMP process, the lower scintillation layer 140L may be divided into a plurality of lower scintillation patterns 140. By the first CMP process, the radiation source layer 150L may be divided into a plurality of radiation sources 150. An upper surface of each of the plurality of second layers 120, an upper surface of each of the plurality of lower scintillation patterns 140, and an upper surface of each of the plurality of radiation sources 150 may be coplanar with an upper surface 110U of the substrate 110.

Referring now to FIGS. 39, 42, and 43, in step P470 of the method of making an integrated battery illustrated in FIG. 39, the plurality of radiation sources 150 may be etched. An etching mask EM may be deposited on the upper surface 110U of the substrate 110. The etching mask EM may expose the radiation sources 150 and cover the plurality of second material layers 120 and the plurality of lower scintillation patterns 140.

The plurality of radiation sources 150 may be etched by anisotropic dry etching. The plurality of radiation sources 150 may be etched by a plasma-based process such as RIE, but aspects of the present disclosure are not limited thereto. A portion of each of the plurality of radiation sources 150 may be removed by an etching process of step P470. Accordingly, the upper surface of each of the plurality of radiation sources 150 may be at a lower level than the upper surface of each of the plurality of second material layers 120, the upper surface of each of the plurality of lower scintillation patterns 140, and the upper surface 110U of the substrate 110. The upper surface of each of the plurality of radiation sources 150 may be between the upper surface 110U of the substrate 110 and a lower surface 110L of the substrate 110. After the plurality of radiation sources 150 are etched, the etching mask EM may be removed by ashing, O₂ plasma treatment, or wet strip.

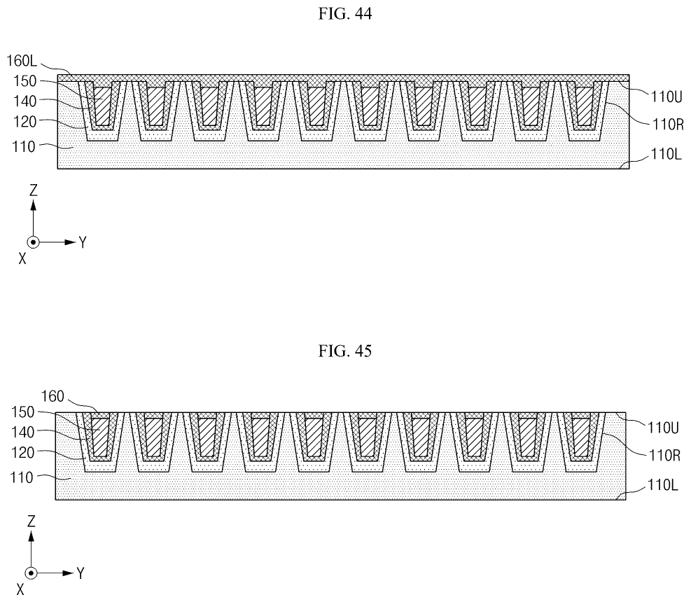

Referring now to FIGS. 39 and 44, in step P480 of the method of making an integrated battery illustrated in FIG. 39, an upper scintillation layer 160L may be formed. The upper scintillation layer 160L may be formed by a deposition process such as CVD. The upper scintillation layer 160L may cover at least a portion of the upper surface 110U of the substrate 110. The upper scintillation layer 160L may cover at least a portion of the upper surfaces of each of the plurality of radiation sources 150. The upper scintillation layer 160L may have a uniform thickness. The upper scintillation layer 160L may have a conformal shape. The upper scintillation layer 160L may comprise a material that emits photons in response to high-energy radiation. The upper scintillation layer 160L may include one or more of the materials that may be included in the previously described lower scintillation layer 140L. The upper scintillation layer 160L may include the same material as the lower scintillation layer 140L, but aspects of the present disclosure are not limited thereto. The upper scintillation layer 160L may include a material different from that of the lower scintillation layer 140L.

Referring now to FIGS. 39, 44, and 45, in step P490 of the method of making an integrated battery illustrated in FIG. 39, a plurality of upper scintillation patterns 160 may be formed. The plurality of upper scintillation patterns 160 may be formed by performing CMP using the upper surface 110U of the substrate 110 as an end point. The upper scintillation layer 160L may be divided into a plurality of upper scintillation patterns 160 by the CMP process.

According to aspects, the plurality of upper scintillation patterns 160 and the plurality of lower scintillation patterns 140 may be formed integrally. According to aspects, each of the plurality of upper scintillation patterns 160 may form a layer continuous with a corresponding one of the plurality of lower scintillation patterns 140. According to aspects, there may be no observable interface between the plurality of upper scintillation patterns 160 and the plurality of lower scintillation patterns 140.

According to aspects, the plurality of upper scintillation patterns 160 and the plurality of lower scintillation patterns 140 may be distinguished from each other. According to aspects, the plurality of upper scintillation patterns 160 and the plurality of lower scintillation patterns 140 may be separate layers that are distinct from each other. According to aspects, there may be an observable interface between each of the plurality of upper scintillation patterns 160 and each of the plurality of lower scintillation patterns 140.

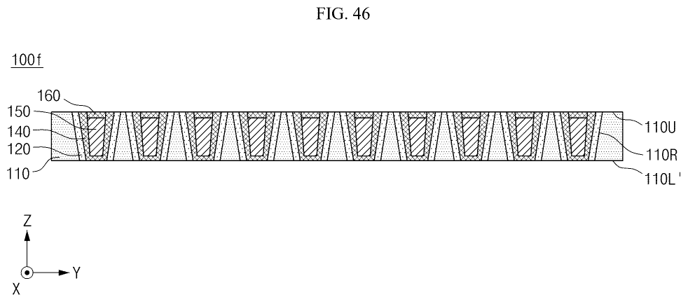

Referring now to FIGS. 39 and 46, in step P500 of the method of making an integrated battery illustrated in FIG. 39, a second CMP process may be performed. The plurality of lower scintillation patterns 140 may be an end point of the second CMP process. By the second CMP process, an integrated battery 100f including the substrate 110, the plurality of second material layers 120, the plurality of lower scintillation patterns 140, the plurality of radiation sources 150, and the plurality of upper scintillation patterns 160 may be formed.

The plurality of recesses 110R of FIG. 45 may become a plurality of holes 110H extending to a new lower surface 110L′ of the substrate 110. Each of the plurality of holes 110H may penetrate the substrate 110. Each of the plurality of second material layers 120 may be in one of the plurality of holes 110H. Each of the plurality of lower scintillation patterns 140 may be in one of the plurality of holes 110H. Each of the plurality of radiation sources 150 may be in one of the plurality of holes 110H. Each of the plurality of upper scintillation patterns 160 may be in one of the plurality of holes 110H.

Each of the plurality of radiation sources 150 may be surrounded by one of the plurality of lower scintillation patterns 140 and one of the plurality of upper scintillation patterns 160. In such aspects, high-energy radiation emitted from the plurality of radiation sources 150 may be converted into photons by the plurality of lower scintillation patterns 140 and the plurality of upper scintillation patterns 160 to prevent the substrate 110 and the plurality of second material layers 120 from being damaged due to the high-energy radiation.

Each of the plurality of radiation sources 150 may have a tapered shape. The plurality of radiation sources 150 may be spaced apart from the plurality of second material layers 120. Each of the plurality of lower scintillation patterns 140 may be between one of the plurality of radiation sources 150 and one of the plurality of second material layers 120. Each of the plurality of upper scintillation patterns 160 may be on one of the plurality of radiation sources 150.

Aspects of the present disclosure have been described above in detail with reference to the drawings. However, the configurations illustrated in the drawings and the aspects described in the present specification are only examples of the technical features of the present disclosure and do not reflect all the technical ideas of the present disclosure. Thus, it should be understood that various equivalents and modifications to the described or depicted configurations would have been made at the filing date of the present application.

1. An integrated battery comprising:
a substrate comprising a first material;
a plurality of second material layers each comprising a second material; and
a plurality of radiation sources configured to apply radiation to the substrate and the plurality of second material layers,
wherein the first material has a polarity opposite a polarity of the second material,
wherein the plurality of second material layers contact the substrate, and
wherein each of the plurality of radiation sources has a tapered shape.

2. The integrated battery of claim 1, wherein the substrate includes a plurality of holes extending into the substrate in a first direction from a first surface of the substrate, wherein the first direction is perpendicular to the first surface of the substrate, and
wherein each radiation source of the plurality of radiation sources is in a respective one of the plurality of holes.

3. The integrated battery of claim 2, wherein each hole of the plurality of holes has a tapered shape.

4. The integrated battery of claim 2, wherein each radiation source of the plurality of radiation sources has a cross-sectional area in a plane normal to the first direction and the cross-sectional area decreases as a distance from the first surface of the substrate in the first direction increases.

5. The integrated battery of claim 2, wherein each second material layer of the plurality of second material layers has a uniform thickness.

6. The integrated battery of claim 2, wherein each second material layer of the plurality of second material layers is between the substrate and a respective radiation source of the plurality of radiation sources.

7. The integrated battery of claim 2, wherein the plurality of holes are arranged in a honeycomb structure in a plane normal to the first direction.

8. The integrated battery of claim 2, wherein the plurality of holes form a plurality of hole arrays such that the plurality of holes are aligned in a second direction and such that the plurality of holes are staggered in a third direction, wherein the second direction is normal to the first direction, and wherein the third direction is normal to the first direction and the second direction.

9. The integrated battery of claim 2, wherein the plurality of holes are arranged in a matrix.

10. The integrated battery of claim 2, wherein each hole of the plurality of holes has an elongated shape extending in a third direction, wherein the third direction is perpendicular to the first direction.

11. The integrated battery of claim 2, wherein each hole of the plurality of holes has a roughened surface.

12. The integrated battery of claim 2, wherein each hole of the plurality of holes has a star shaped cross-section in a plane perpendicular to the first direction.

13. The integrated battery of claim 2, wherein an interface between the substrate and each second material layer of the plurality of second material layers is roughened.

14. The integrated battery of claim 2, wherein an interface between each second material layer of the plurality of second material layers and each radiation source of the plurality of radiation sources is roughened.

15. The integrated battery of claim 1, wherein each radiation source of the plurality of radiation sources comprises a radioactive isotope that emits beta rays.

16. The integrated battery of claim 1, wherein each radiation source of the plurality of radiation sources comprises a radioactive isotope that emits alpha rays.

17. The integrated battery of claim 16, further comprising a plurality of lower scintillation patterns, wherein the plurality of lower scintillation patterns comprises a material that emits photons in response to the alpha rays.

18. The integrated battery of claim 17, wherein each lower scintillation pattern of the plurality of lower scintillation patterns is between a respective radiation source of the plurality of radiation sources and a respective second material layer of the plurality of second material layers.

19. The integrated battery of claim 18, further comprising a plurality of upper scintillation patterns, wherein the plurality of upper scintillation layers comprises a material that emits photons in response to the alpha rays.

20. The integrated battery of claim 16, wherein each upper scintillation pattern of the plurality of upper scintillation patterns is on an upper surface of a respective radiation source of the plurality of radiation sources.

21. The integrated battery of claim 20, wherein each radiation source of the plurality of radiation sources is surrounded by a respective upper scintillation pattern of the plurality of upper scintillation patterns and a respective lower scintillation pattern of the plurality of lower scintillation patterns.

22. The integrated battery of claim 20, wherein each upper scintillation pattern of the plurality of upper scintillation patterns forms a continuous layer with a respective lower scintillation pattern of the plurality of lower scintillation patterns.

23. An integrated battery comprising a first battery layer, a second battery layer, and an insulating layer between the first battery layer and the second battery layer,
wherein the first battery layer comprises:
a first substrate comprising a first material;
a plurality of second material layers each comprising a second material; and
a plurality of first radiation sources;
wherein the first substrate comprises a plurality of first holes;
wherein each first radiation source of the plurality of first radiation sources is in a respective one of the plurality of first holes;
wherein each of the plurality of second material layers is between the substrate and a respective one of the plurality of first radiation sources;
wherein first material has a polarity opposite a polarity of the second material;
wherein the second battery layer comprises:
a second substrate comprising a third material;
a plurality of fourth material layers each comprising a fourth material; and
a plurality of second radiation sources;
wherein the second substrate comprises a plurality of second holes;
wherein each second radiation source of the plurality of second radiation sources is in a respective one of the plurality of second holes;
wherein each of the plurality of fourth material layers is between the second substrate and a respective one of the plurality of second radiation sources; and
wherein third material has a polarity opposite a polarity of the fourth material.

24. The integrated battery of claim 23, further comprising a plurality of vias extending through the insulating layer, the plurality of vias connecting the first battery layer and the second battery layer.

25. The integrated battery of claim 24, wherein each of the plurality of vias is in contact with one of the plurality of second material layers of the first battery layer and the second substrate of the second battery layer.

26. The integrated battery of claim 24, wherein the plurality of vias electrically connect the first battery layer and the second battery layer in series.

27. The integrated battery of claim 26, wherein the second material of the plurality of second material layers of the first battery layer has the same polarity as the third material of the second substrate of the second battery layer.

28. The integrated battery of claim 24, wherein the plurality of vias electrically connect the first battery layer and the second battery layer in parallel.

29. The integrated battery of claim 28, wherein the second material of the plurality of second material layers of the first battery layer has polarity opposite to the polarity of the third material of the second substrate of the second battery layer.

30. The integrated battery of claim 23, wherein each of the plurality of first radiation sources and each of the plurality of second radiation sources have a tapered shape.

31. The integrated battery of claim 23, wherein each of the plurality of second material layers has a cup shape, and wherein each of the plurality of fourth material layers has a cup shape.

32. The integrated battery of claim 23, wherein each of the plurality of second material layers has a uniform thickness, and wherein each of the plurality of fourth material layers has a uniform thickness.

33. The integrated battery of claim 23, wherein each of the plurality of first holes has a tapered shape and each of the plurality of second holes has a tapered shape.

34. The integrated battery of claim 23, further comprising a core layer comprising peripheral transistors,
wherein the first battery layer is on the core layer.

35. The integrated battery of claim 34, wherein the peripheral transistors form a voltage regulator configured to adjust output voltages of the first battery layer and the second battery layer.

36. An integrated battery comprising:
a substrate comprising a first material, wherein the substrate comprises a plurality of holes;
a plurality of radiation sources in the plurality of holes, wherein each radiation source of the plurality of radiation sources has a necked shape; and
a plurality of second material layers each comprising a second material, wherein each of the plurality of second material layers is between a respective radiation source of the plurality of radiation sources and the substrate, and wherein the first material has a polarity opposite a polarity of the second material.

37. The integrated battery of claim 36, wherein each hole of the plurality of holes has a necked shape.
